(19) United States
(12) Patent Application Publication
(10) Pub. No.: US 2026/0179659 A1
(43) Pub. Date: Jun. 25, 2026

(54) MEMORY DEVICE INCLUDING CONDUCTIVE STRUCTURES AND LANDING STRUCTURES

(71) Applicant: Micron Technology, Inc., Boise, ID (US)

(72) Inventors: Shuangqiang Luo, Boise, ID (US); Ian Harrison, Boise, ID (US); Jiewei Chen, Meridian, ID (US); Sundar Rajarajan, San Jose, CA (US); Indra V. Chary, Boise, ID (US); Kyle A. Ritter, Boise, ID (US); Mallesh Rajashekharaiah, Boise, ID (US)

(21) Appl. No.: 18/990,638

(22) Filed: Dec. 20, 2024

(51) Int. Cl. G11C 5/06; H10B 41/10; H10B 41/27; H10B 43/10; H10B 43/27

(52) U.S. Cl. CPC G11C 5/06; H10B 41/10; H10B 41/27; H10B 43/10; H10B 43/27

(57) ABSTRACT

Some embodiments include apparatuses and methods of forming the apparatuses. One of the methods includes: a first structure including at least one level of material; a second structure of materials formed in the first structure; levels of conductive materials interleaved with levels of dielectric materials, the levels of conductive materials and levels of dielectric materials located over the first structure and the second structure; a memory cell pillar extending through the levels of conductive materials and the levels of dielectric materials; and a conductive contact extending through the levels of conductive materials and the levels of dielectric materials and contacting one of the levels of conductive materials, the conductive contact including a portion adjacent the second structure.

### BACKGROUND

A memory device (e.g., a flash memory device) has numerous tiers of memory cells and associated control gates. The memory device also has conductive structures to provide signals to the control gates and other parts of the memory device. In some conventional memory devices, such conductive structures often extend through the tiers and make electrical contacts with other conductive elements and circuitry of the memory device. Dimensions of structures of a memory device are relatively small (e.g., in nanometer size). At a certain dimension, improperly forming such conductive structures can negatively impact the reliability and performance of the memory device.

### BRIEF DESCRIPTION OF THE DRAWINGS

FIG. 1 shows an apparatus in the form of a memory device, according to some embodiments described herein.

FIG. 2 shows a schematic of an apparatus in the form of a memory device having a memory array and memory cell blocks, according to some embodiments described herein.

FIG. 3A shows a top view of a structure of the memory device of FIG. 2 including a memory array, staircase regions, and dielectric structures between memory cell blocks of the memory device, according to some embodiments described herein.

FIG. 3B shows a top view of a portion of the memory device of FIG. 3A, according to some embodiments described herein.

FIG. 3C shows a portion (e.g., a side view) in the Y-Z direction of the memory device of FIG. 3B, according to some embodiments described herein.

FIG. 3D shows a portion of the memory device of FIG. 3B including a portion (e.g., a side view) in the X-Z direction of the memory device, according to some embodiments described herein.

FIG. 3E shows another portion of the memory device of FIG. 3B including a portion (e.g., a side view) in the X-Z direction of the memory device, according to some embodiments described herein.

FIG. 3F shows an alternative structure of the memory device of FIG. 3B, according to some embodiments described herein.

FIG. 3G shows a portion of the memory device of FIG. 3F including a portion (e.g., a side view) in the X-Z direction of the memory device of FIG. 3F, according to some embodiments described herein.

FIG. 3H, FIG. 3I, and FIG. 3J show different views of an alternative structure of the memory device of FIG. 3C, FIG. 3D, and FIG. 3E, respectively, according to some embodiments described herein.

FIG. 3K shows an alternative liner of a conductive contact of the memory device of FIG. 3D, according to some embodiments described herein.

FIG. 3L, FIG. 3M, and FIG. 3N shows a conductive contact and structures (e.g., pillar structures) and corresponding widths and thickness, according to some embodiments described herein.

FIG. 4A through FIG. 16B show different views of structures during processes of forming the memory device of FIG. 2 through FIG. 3N, according to some embodiments described herein.

### DETAILED DESCRIPTION

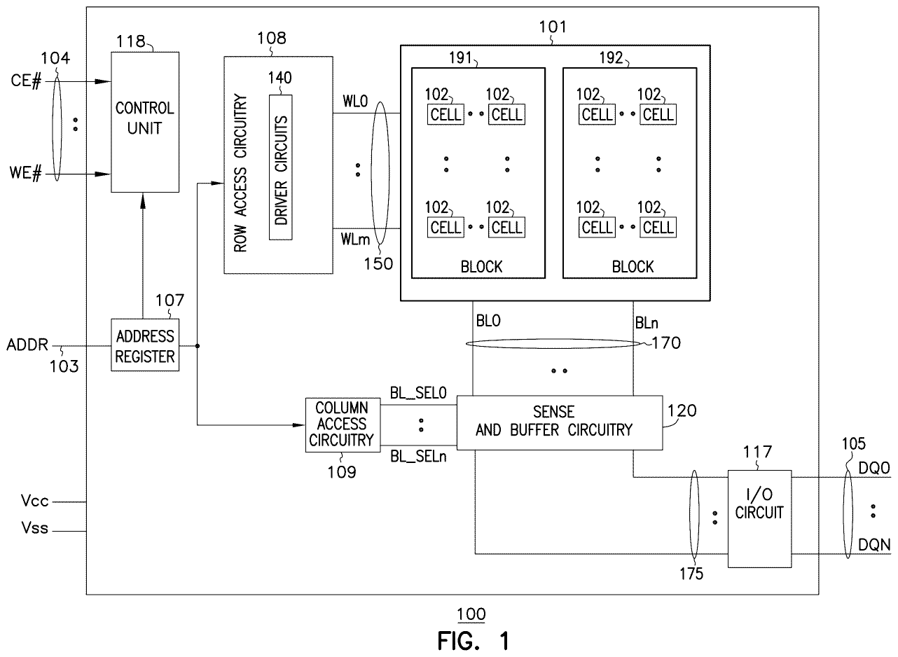

The techniques described herein involve a memory device including memory cells formed in tiers (different physical levels) of the memory device. The tiers include respective levels of conductive materials. The conductive materials form part of control gates (e.g., word lines) associated with the memory cells. The described memory device includes conductive contacts associated with the control gates. The described memory device also includes pillar structures. The conductive contacts and the pillar structures extend through the levels of conductive materials. The described memory device also includes landing structures associated with (e.g., formed under) the conductive contacts and the pillar structures. The techniques described herein also involve processes of forming the described memory device. As described in more detail below, the techniques described herein can improve reliability and performance of the memory device. Other improvements and benefits of the techniques described herein are further discussed below with reference to FIG. 1 through FIG. 16B.

FIG. 1 shows an apparatus in the form of a memory device 100, according to some embodiments described herein. Memory device 100 can include a memory array (or multiple memory arrays) 101 containing memory cells 102 arranged in blocks (blocks of memory cells), such as blocks 191 and 192. In the physical structure of memory device 100, memory cells 102 can be arranged vertically (e.g., stacked one over another) over a substrate (e.g., a semiconductor substrate) of memory device 100. FIG. 1 shows memory device 100 having two blocks 191 and 192 as an example. Memory device 100 can have more than two blocks.

As shown in FIG. 1, memory device 100 can include access lines 150 and data lines 170. Access lines 150 can include word lines, which can include global word lines and local word lines (e.g., control gates). Data lines 170 can include bit lines (e.g., local bit lines). Access lines 150 can carry signals (e.g., word line signals) WL0 through WLm. Data lines 170 can carry signals (e.g., bit line signals) BL0 through BLn. Memory device 100 can use access lines 150 to selectively access memory cells 102 of blocks 191 and 192 and data lines 170 to selectively exchange information (e.g., data) with memory cells 102.

Memory device 100 can include an address register 107 to receive address information (e.g., address signals) ADDR on lines (e.g., address lines) 103. Memory device 100 can include row access circuitry 108 and column access circuitry 109 that can decode address information from address register 107. Based on decoded address information, memory device 100 can determine which memory cells 102 of which blocks 191 and 192 are to be accessed during a memory operation. Memory device 100 can include drivers (driver circuits) 140, which can be part of row access circuitry 108. Drivers 140 can operate (e.g., operate as switches) to form (or not to form) conductive paths (e.g., current paths) between nodes providing voltages and respective access lines 150 during operations of memory device 100.

Memory device 100 can perform a read operation to read (e.g., sense) information (e.g., previously stored information) from memory cells 102 of blocks 191 and 192, or a write (e.g., programming) operation to store (e.g., program) information in memory cells 102 of blocks 191 and 192. Memory device 100 can use data lines 170 associated with signals BL0 through BLn to provide information to be stored in memory cells 102 or obtain information read (e.g., sensed) from memory cells 102. Memory device 100 can also perform an erase operation to erase information from some or all of memory cells 102 of blocks 191 and 192.

Memory device 100 can include a control unit 118 that can be configured to control memory operations of memory device 100 based on control signals on lines 104. Examples of the control signals on lines 104 include one or more clock signals and other signals (e.g., a chip-enable signal CE#, a write-enable signal WE#) to indicate which operation (e.g., read, write, or erase operation) memory device 100 can perform. Other devices external to memory device 100 (e.g., a memory controller or a processor) may control the values of the control signals on lines 104. Specific values of a combination of the signals on lines 104 may produce a command (e.g., read, write, or erase command) that may cause memory device 100 to perform a corresponding memory operation (e.g., read, write, or erase operation).

Memory device 100 can include sense and buffer circuitry 120 that can include components such as sense amplifiers and page buffer circuits (e.g., data latches). Sense and buffer circuitry 120 can respond to signals BL_SEL0 through BL_SELn from column access circuitry 109. Sense and buffer circuitry 120 can be configured to determine (e.g., by sensing) the value of information read from memory cells 102 (e.g., during a read operation) of blocks 191 and 192 and provide the value of the information to lines 175, which can include global data lines (e.g., global bit lines). Sense and buffer circuitry 120 can also be configured to use signals on lines 175 to determine the value of information to be stored (e.g., programmed) in memory cells 102 of blocks 190 and 191 (e.g., during a write operation) based on the values (e.g., voltage values) of signals on lines 175 (e.g., during a write operation).

Memory device 100 can include input/output (I/O) circuitry 117 to exchange information between memory cells 102 of blocks 191 and 192 and lines (e.g., I/O lines) 105. Signals DQ0 through DQN on lines 105 can represent information read from or stored in memory cells 102 of blocks 191 and 192. Lines 105 can include nodes within memory device 100 or pins (or solder balls) on a package where memory device 100 can reside. Other devices external to memory device 100 (e.g., a memory controller or a processor) can communicate with memory device 100 through lines 103, 104, and 105.

Memory device 100 can receive a supply voltage, including supply voltages Vcc and Vss. Supply voltage Vss can operate at a ground potential (e.g., having a value of approximately zero volts). Supply voltage Vcc can include an external voltage supplied to memory device 100 from an external power source such as a battery or alternating current to direct current (AC-DC) converter circuitry.

Each of memory cells 102 can be programmed to store information representing a value of at most one bit (e.g., a single bit), or a value of multiple bits such as two, three, four, or another number of bits. For example, each of memory cells 102 can be programmed to store information representing a binary value “0” or “1” of a single bit. The single bit per cell is sometimes called a single-level cell. In another example, each of memory cells 102 can be programmed to store information representing a value for multiple bits, such as one of four possible values “00”, “01”, “10”, and “11” of two bits, one of eight possible values “000”, “001”, “010”, “011”, “100”, “101”, “110”, and “111” of three bits, or one of other values of another number of multiple bits. A cell that has the ability to store multiple bits is sometimes called a multi-level cell (or multi-state cell).

Memory device 100 can include a non-volatile memory device, and memory cells 102 can include non-volatile memory cells, such that memory cells 102 can retain information stored thereon when power (e.g., voltage Vcc, Vss, or both) is disconnected from memory device 100. For example, memory device 100 can be a flash memory device, such as a NAND flash (e.g., 3-dimensional (3-D) NAND) or a NOR flash memory device, or another kind of memory device, such as a variable resistance memory device (e.g., a phase change memory device or a resistive Random-Access Memory (RAM) device.

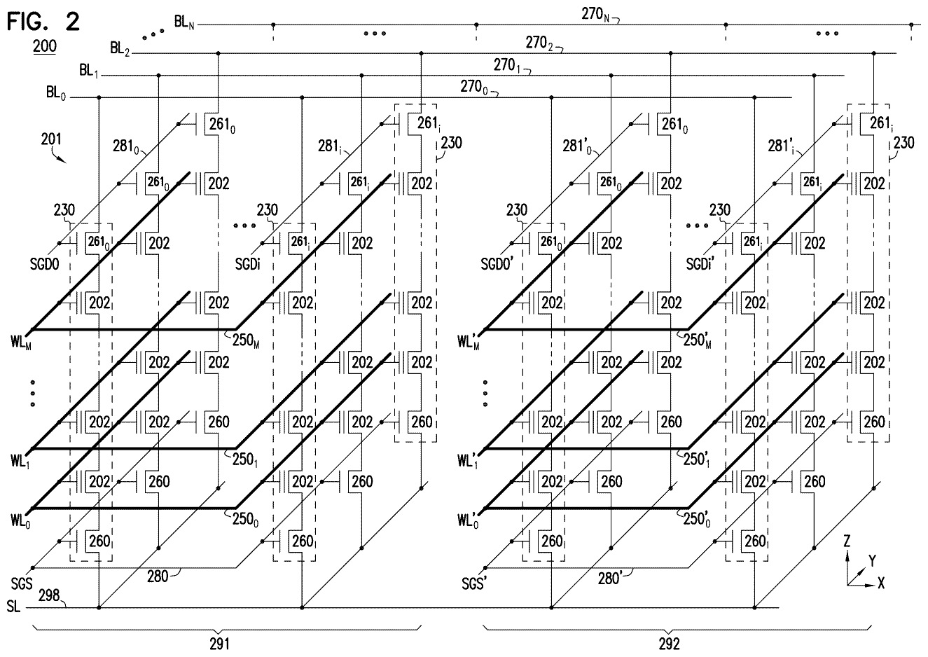

One of ordinary skill in the art may recognize that memory device 100 may include other components, several of which are not shown in FIG. 1 so as not to obscure the example embodiments described herein. At least a portion of memory device 100 can include structures and perform operations similar to or identical to the structures and operations of any of the memory devices described below with reference to FIG. 2 through FIG. 16B.

FIG. 2 shows a schematic of an apparatus in the form of a memory device 200 having a memory array 201 and blocks (e.g., memory cell blocks) 291 and 292, according to some embodiments described herein. Memory device 200 can include a non-volatile (e.g., NAND flash memory device) or other types of memory devices. Memory device 200 can correspond to memory device 100. For example, memory array (or multiple memory arrays) 201 and blocks 291 and 292 can correspond to memory array 101 and blocks 191 and 192, respectively, of memory device 100 of FIG. 1.

As shown in FIG. 2, memory device 200 can include memory cells 202, data lines 270₀ through 270_{N} (270₀-270_{N}), control gates 250₀ through 250_{M} in block 291, and control gates 250′₀ through 250′_{M} in block 292. Data lines 270₀-270_{N} can correspond to part of data lines 170 of memory device 100 of FIG. 1. In FIG. 2, label “N” (index N) next to a number (e.g., 270_{N}) represents the number of data lines of memory device 200. For example, if memory device 200 includes 16 data lines, then N is 15 (data lines 270₀ through 270₁₅). In FIG. 2, label “M” (index M) next to a number (e.g., 250_{M}) represents the number of control gates of memory device 200. For example, if memory device 200 includes 128 control gates, then M is 127 (control gates 250₀ through 250₁₂₇). Memory device 200 can have the same number of control gates (e.g., M−1 control gates) among the blocks (e.g., blocks 291 and 292) of memory device 200.

In FIG. 2, data lines 270₀-270_{N} can include (or can be part of) bit lines (e.g., local bit lines) of memory device 200. As shown in FIG. 2, data lines 270₀-270_{N} can carry signals (e.g., bit line signals) BL₀ through BL_{N}, respectively. In the physical structure of memory device 200, data lines 270₀-270_{N} can be structured as conductive lines and have respective lengths extending in the X-direction (e.g., a direction from one memory block to another).

As shown in FIG. 2, memory cells 202 can be organized into separate blocks (memory cell blocks or blocks of memory cells) such as blocks 291 and 292. FIG. 2 shows memory device 200 including two blocks 291 and 292 as an example. However, memory device 200 can include numerous blocks. The blocks (e.g., blocks 291 and 292) of memory device 200 can share data lines (e.g., data lines 270₀-270_{N}) to carry information (in the form of signals) read from or to be stored in memory cells of selected memory cells (e.g., selected memory cells in block 291 or 292) of memory device 200.

Control gates 250₀-250_{M} in block 291 can be part of local word lines, which can be part of (or can be coupled to) access lines (e.g., global word lines) of memory device 200 that can correspond to access lines 150 of memory device 100 of FIG. 1. Control gates 250′₀-250′_{M} in block 292 can be another part of other local word lines, which can be part of access lines (e.g., global word lines) of memory device 200. Control gates 250₀-250_{M} can be electrically separated from control gates 250′₀-250′_{M}. Thus, blocks 291 and 292 can be accessed separately (e.g., accessed one at a time). For example, block 291 can be accessed at one time using control gates 250₀-250_{M}, and block 292 can be accessed at another time using control gates 250′₀-250′_{M} at another time.

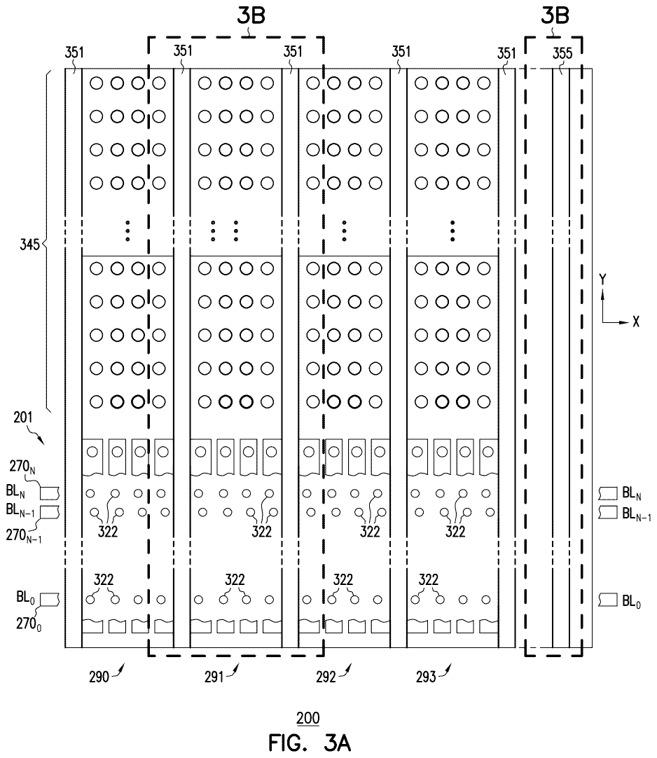

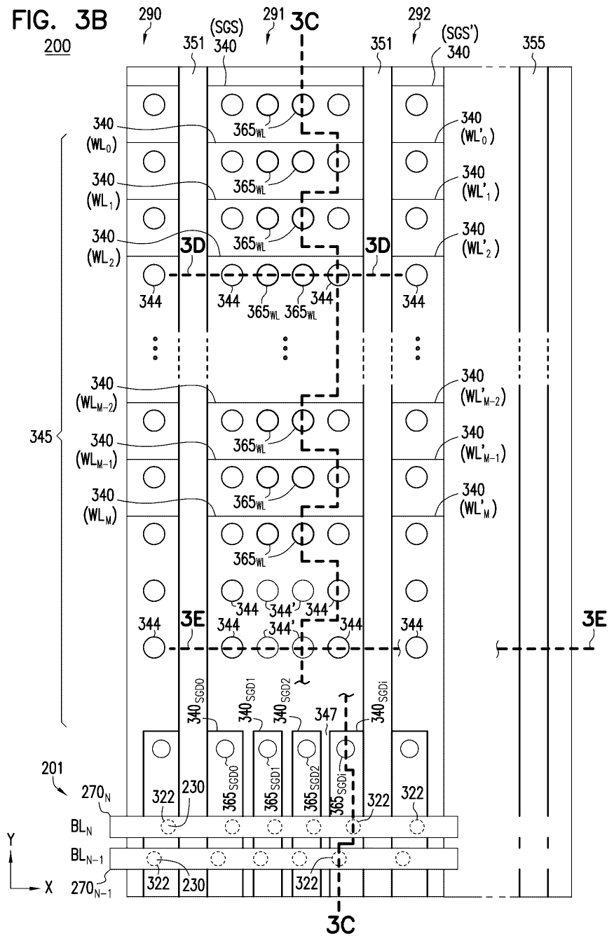

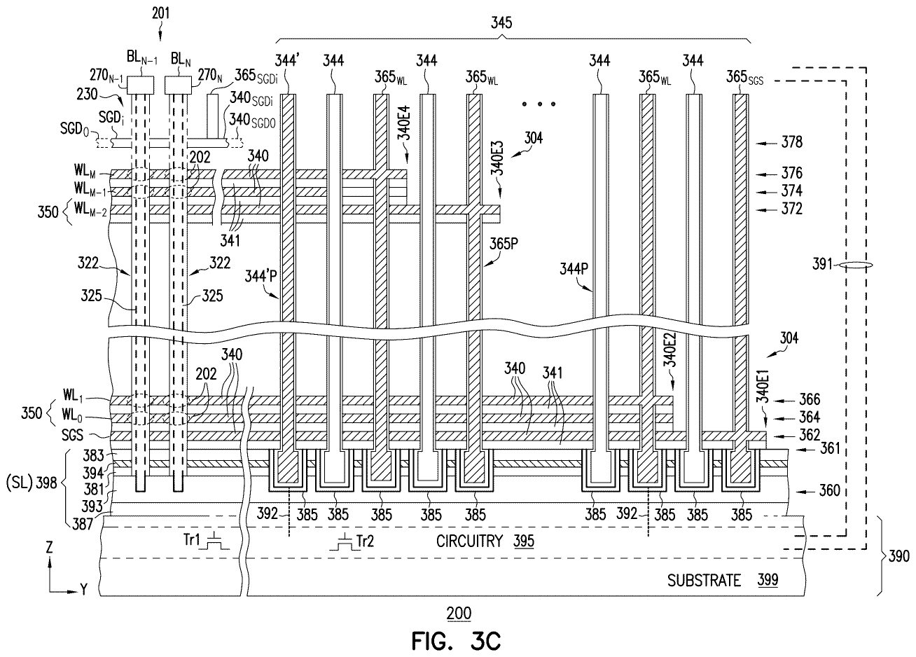

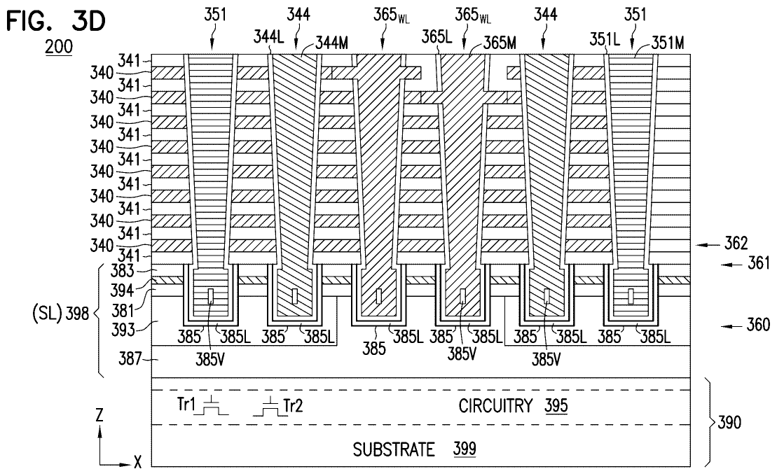

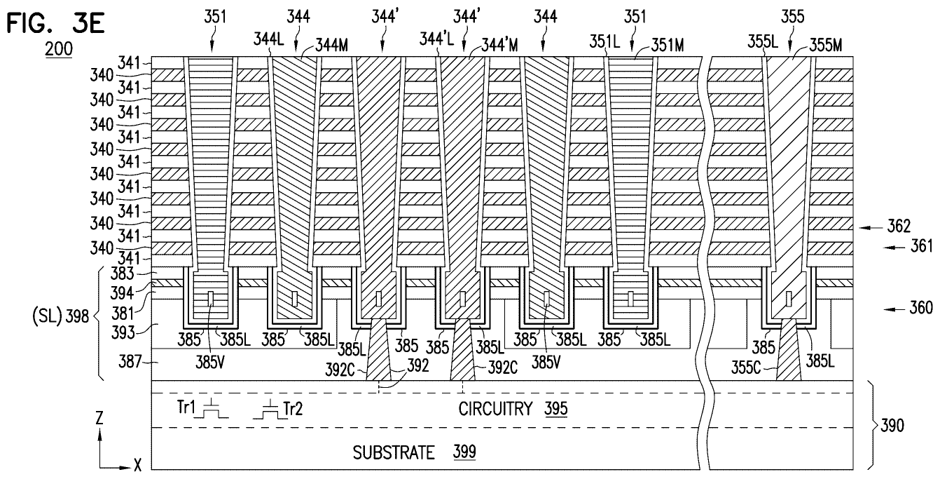

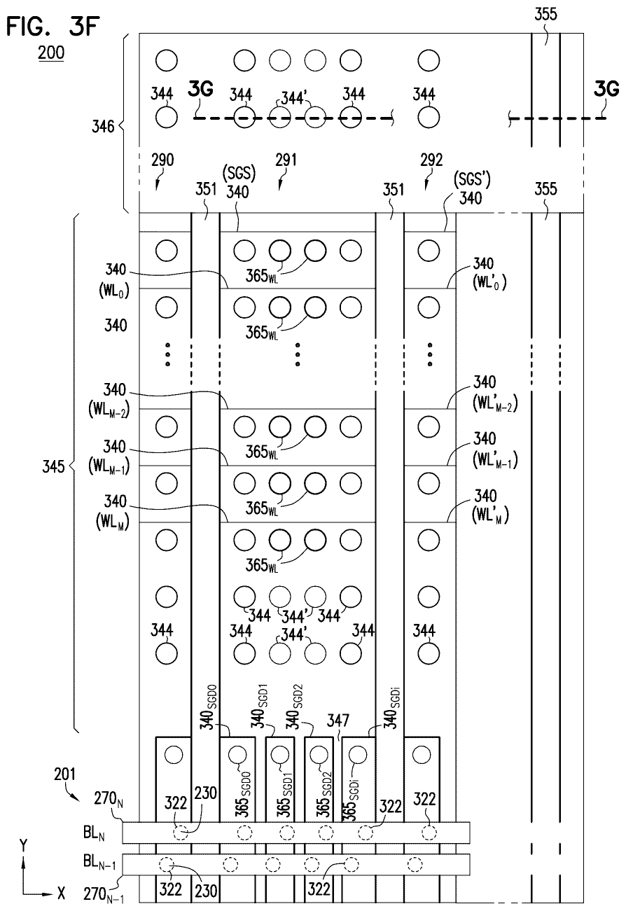

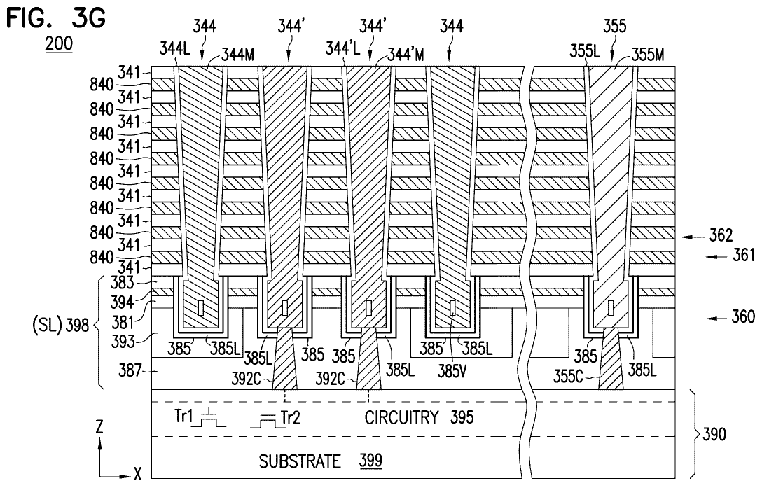

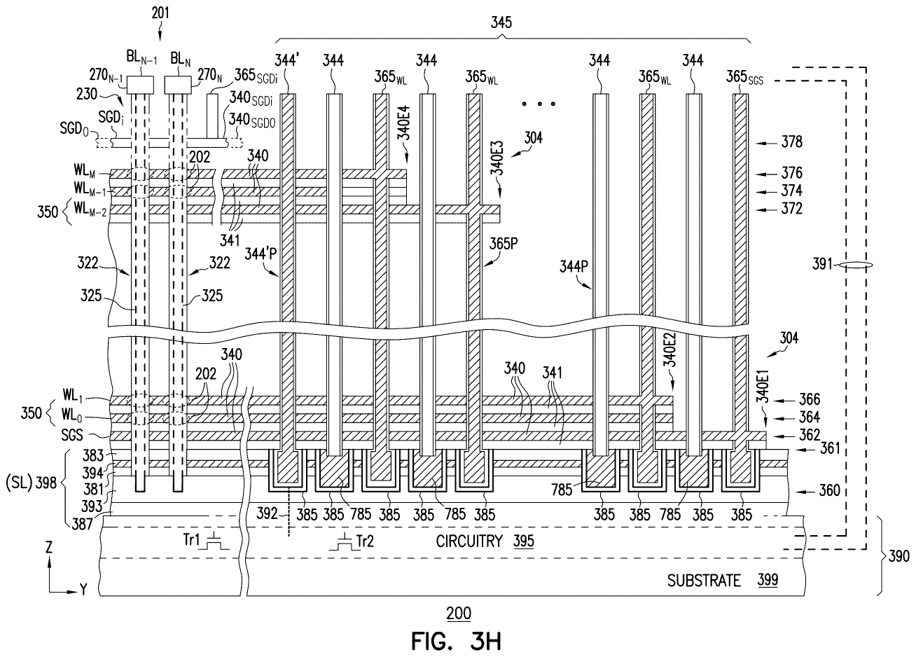

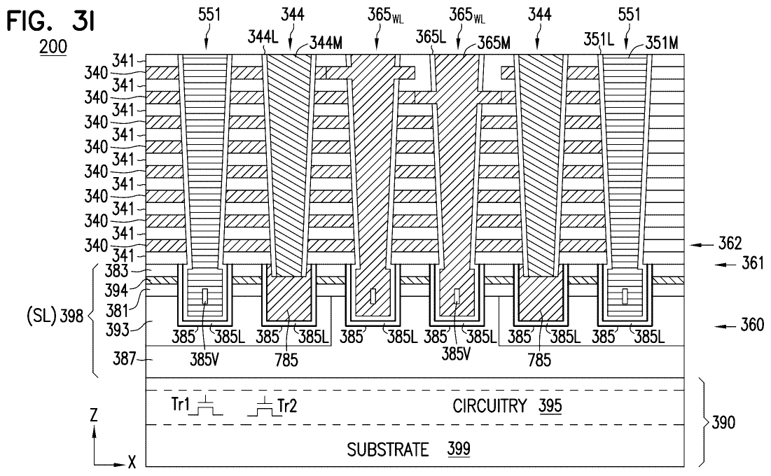

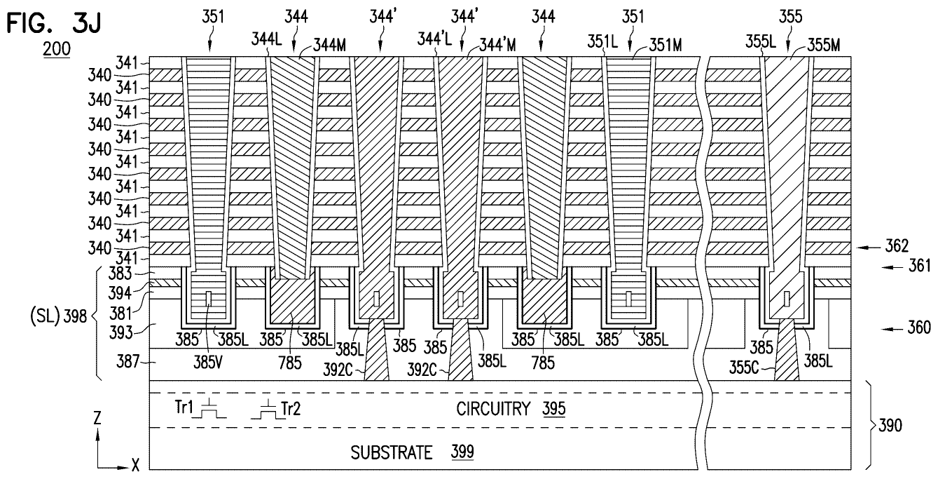

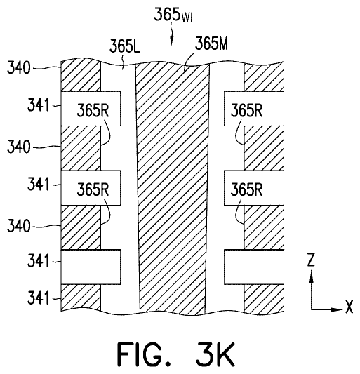

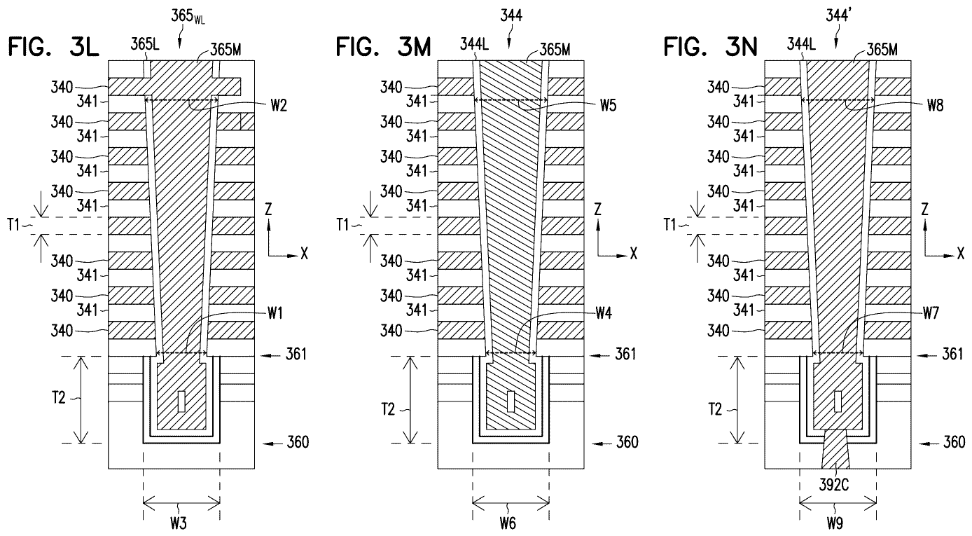

FIG. 2 shows directions X, Y, and Z that can be relative to the physical directions (e.g., dimensions) of the structure of memory device 200. For example, the Z-direction can be a direction perpendicular to (e.g., vertical direction with respect to) a substrate of memory device 200 (e.g., a substrate 399 shown in FIG. 3C). The Z-direction is perpendicular to the X-direction and Y-direction (e.g., the Z-direction is perpendicular to an X-Y plane of memory device 200). In the physical structure of memory device 200, control gates 250₀-250_{M} can be formed on different levels (e.g., layers) of memory device 200 in the Z-direction. In this example, the levels (e.g., layers) of control gates 250₀-250_{M} can be formed (e.g., stacked) one level (one layer of material) over another (another layer of material) in the Z-direction.

As shown in FIG. 2, memory cells 202 can be included in respective memory cell strings 230 in each of the blocks (e.g., blocks 291 and 292) of memory device 200. Each of memory cell strings 230 can have series-connected memory cells (e.g., M+1 (e.g., 128) series-connected memory cells) in the Z-direction. In a physical structure of memory device 200, memory cells 202 in each of memory cell strings 230 can be formed (e.g., stacked vertically one over another) in different levels (e.g., M+1 (e.g., 128) layers in the example of FIG. 2) in the Z-direction of memory device 200. Memory cells 202 of a respective memory cell string 230 can be associated with a respective memory cell pillar (e.g., pillar 322 shown in FIG. 3C). The number of memory cells in each of memory cell strings 230 can be equal to the number of levels (e.g., layers) of control gates (e.g., control gates 250₀-250_{M}) of memory device 200. For example, if each memory cell string 230 has 128 (e.g., M=127) memory cells 202, then there are 128 corresponding levels of control gates 250₀-250_{M} for the 128 memory cells.

As shown in FIG. 2, control gates 250₀-250_{M} can carry corresponding signals WL₀-WL_{M}. As mentioned above, control gates 250₀-250_{M} can include (or can be parts of) access lines (e.g., word lines) of memory device 200. Each of control gates 250₀-250_{M} can be part of a structure (e.g., a level) of a conductive material (e.g., a layer of conductive material) located in a level of memory device 200. Memory device 200 can use signals WL₀-WL_{M} to selectively control access to memory cells 202 of block 291 during an operation (e.g., read, write, or erase operation). For example, during a read operation, memory device 200 can use signals WL₀-WL_{M} to control access to memory cells 202 of block 291 to read (e.g., sense) information (e.g., previously stored information) from memory cells 202 of block 291. In another example, during a write operation, memory device 200 can use signals WL₀-WL_{M} to control access to memory cells 202 of block 291 to store information in memory cells 202 of block 291.

Like control gates 250₀-250_{M} in block 291, control gates 250′₀-250′_{M} in block 292 can carry corresponding signals WL′₀-WL′_{M}. Each of control gates 250′₀-250′_{M} can be part of a structure (e.g., a level) of a conductive material (e.g., a layer of conductive material) located in a single level of memory device 200. Control gates 250′₀-250′_{M} can be located in the same levels (in the Z-direction) as control gates 250₀-250_{M}, respectively. As mentioned above, control gates 250′₀-250′_{M} (e.g., local word lines) can be electrically separated from control gates 2500-250M (e.g., other local word lines)

Memory device 200 can use signals WL′₀-WL′_{M} to control access to memory cells 202, respectively, of block 292 during an operation (e.g., read, write, or erase operation). For example, during a read operation, memory device 200 can use signals WL′₀-WL′_{M} to control access to memory cells 202 of block 292 to read (e.g., sense) information (e.g., previously stored information) from memory cells 202 of block 292. In another example, during a write operation, memory device 200 can use signals WL′₀-WL′_{M} to control access to memory cells 202 of block 292 to store information in memory cells 202 block 292.

As shown in FIG. 2, memory cells in different memory cell strings in the same block can share (e.g., can be controlled by) the same control gate in that block. For example, in block 291, memory cells 202 coupled to control gate 250₀ can share (can be controlled by) control gate 250₀. In another example, memory cells 202 coupled to control gate 250₁ can share (can be controlled by) control gate 250₁. In another example, in block 292, memory cells 202 coupled to control gate 250′₀ can share (can be controlled by) control gate 250′₀. In another example, memory cells 202 coupled to control gate 250′₁ can share (can be controlled by) control gate 250′₁.

Memory device 200 can include a source (e.g., a source line, a source plate, or a source region) 298. Source 298 can be part of (or can include) a structure (e.g., source structure) 398 shown in FIG. 3C that can carry a signal (e.g., a source line signal) SL. Source 298 can be common conductive region (e.g., common source plate or common source region) of block 291 and 292. Source 298 can be coupled to a ground connection (e.g., ground plate) of memory device 200. Alternatively, source 298 can be coupled to a connection (e.g., a conductive region) that is different from a ground connection.

As shown in FIG. 2, memory device 200 can include select transistors (e.g., drain select transistors) 261₀ through 261ᵢ (261₀-261ᵢ) and select gates (e.g., drain select gates) 281₀ through 281ᵢ in block 291. Transistors 261₀ can share the same select gate 281₀. Transistors 261ᵢ can share the same select gate 281ᵢ. Select gates 281₀-281ᵢ can carry signals SGD0 through SGDi, respectively.

Transistors 261₀-261ᵢ can be controlled (e.g., turned on or turned off) by signals SGD0-SGDi, respectively. During a memory operation (e.g., a read or write operation) of memory device 200, transistors 261₀ and transistors 261ᵢ can be turned on one group at a time (e.g., either the group of transistors 261₀ or the group of transistors 261ᵢ can be turned on at a time). Transistors 261₀ can be turned on (e.g., by activating respective signals SGD0) to couple memory cell strings 230 of block 291 to respective data lines 270₀-270_{N}. Transistors 261ᵢ can be turned on (e.g., by activating respective signals SGDi) to couple memory cell strings 230 of block 291 to respective data lines 270₀-270_{N}. Transistors 261₀-261ᵢ can be turned off (e.g., by deactivating respective signals SGD0-SGDi) to decouple the memory cell strings 230 of block 291 from respective data lines 270₀-270_{N}.

Memory device 200 can include transistors (e.g., source select transistors) 260 in block 291, each of which can be coupled between source 298 and memory cells 202 in a respective memory cell string (one of memory cell strings 230) of block 291. Memory device 200 can include a select gate (e.g., source select gate) 280. Transistors 260 in block 291 can share select gate 280. Transistors 260 in block 291 can be controlled (e.g., turned on or turned off) by the same signal, such as SGS signal (e.g., source select gate signal) provided on select gate 280. During a memory operation (e.g., a read or write operation) of memory device 200, transistors 260 in block 291 can be turned on (e.g., by activating an SGS signal) to couple the memory cell strings of block 291 to source 298. Transistors 260 in block 291 can be turned off (e.g., by deactivating the SGS signal) to decouple the memory cell strings of block 291 from source 298.

Memory device 200 can include similar elements among the blocks (e.g., blocks 291 and 292). For example, in block 292, memory device 200 can include select gates (e.g., drain select gates) 281′₀ through 281′ᵢ, and transistors (e.g., drain select transistors) 261₀-261ᵢ. Transistors 261₀ of block 292 can share the same select gate 281′₀. Transistors 261ᵢ of block 292 can share the same select gate 281′ᵢ. Select gates 281′₀ through 281′ᵢ can carry signals SGD0′ through SGDi′, respectively. Transistors 261₀-261ᵢ of block 292 can be controlled (e.g., turned on or turned off) by signals SGD0′ through SGDi′, respectively. During a memory operation (e.g., a read or write operation) of memory device 200, the group of transistors 261₀ and the group of transistors 261ᵢ of block 292 can be turned on (e.g., by activating respective signals SGD0′ through SGDi′) one group at a time to couple respective memory cell strings of block 292 to data lines 270₀-270_{N}. Transistors 261₀-261ᵢ of block 292 can be turned off (e.g., by deactivating respective signals SGD0′ through SGDi′) to decouple the memory cell strings of block 292 from respective sets of data lines 270₀-270_{N}.

Memory device 200 can include transistors (e.g., source select transistors) 260 in block 292, each of which can be coupled between source 298 and the memory cells in a respective memory cell string of block 292. Transistors 260 of block 292 can share the same select gate (e.g., source select gate) 280′ of memory device 200. Transistors 260 of block 292 can be controlled (e.g., turned on or turned off) by the same signal, such as SGS′ signal (e.g., source select gate signal) provided on select gate 280′. During a memory operation (e.g., a read or write operation) of memory device 200, transistors 260 of block 292 can be turned on (e.g., by activating an SGS′ signal) to couple the memory cell strings of block 292 to source 298. Transistors 260 of block 292 can be turned off (e.g., by deactivating the SGS′ signal) to decouple the memory cell strings of block 292 from source 298. FIG. 2 shows select gates 280 and 280′ being electrically separated from each other as an example. Alternatively, select gates 280 and 280′ can be electrically coupled to each other.

Memory device 200 includes other components, which are not shown in FIG. 2 so as not to obscure the example embodiments described herein. Some of the structures of memory device 200 are described below with reference to FIG. 3A through FIG. 16B. For simplicity, detailed description of the same element among the drawings (FIG. 1 through FIG. 16B) is not repeated.

FIG. 3A shows a top view of a structure of memory device 200 including a memory array 201, a region 345, dielectric structures (e.g., block dividers) 351 between respective blocks 290, 291, 292, and 293, and a structure 355, according to some embodiments described herein. In the figures (drawings) herein, similar or the same elements of memory device 200 of FIG. 2 and other figures (e.g., FIG. 3A through FIG. 16B) are given the same labels. Detailed descriptions of similar or the same elements may not be repeated from one figure to another figure. For simplicity, cross-sectional lines (e.g., hatch lines) are omitted from some or all of the elements shown in the drawings described herein. Some elements of memory device 200 may be omitted from a particular figure of the drawings so as not to obscure the view or the description of the element (or elements) being described in that particular figure. Further, the dimensions (e.g., physical structures) of the elements shown in the drawings described herein are not scaled.

As shown in FIG. 3A, blocks (blocks of memory cells) 290, 291, 292, and 293 (290-293) of memory device 200 can be located side-by-side from one block to another in the X-direction. Four blocks 290-293 are shown as an example. Memory device 200 can include numerous blocks. Blocks 291 and 292 of FIG. 3A are schematically shown and described above with reference to FIG. 2. Other blocks (e.g., block 290 and 293) of memory device 200 in FIG. 3A are not shown in FIG. 2.

In FIG. 3A, dielectric structures 351 can be formed to divide (e.g., organize) memory device 200 into physical blocks (e.g., blocks 290-293). Dielectric structures 351 can have lengths extending in the Y-direction. Each of dielectric structures 351 can be formed in (or can be located in) a trench (e.g., a slit) between two adjacent blocks.

In FIG. 3A, each of dielectric structures 351 can include any combination (e.g., one or more) of dielectric materials, semiconductor materials, and conductive materials formed in (e.g., filling) a respective trench. Dielectric structures 351 can separate (e.g., physically and electrically separate) one block from another. For example, as shown in FIG. 3A, dielectric structure 351 between blocks 290 and 291 can separate block 291 from block 290. Dielectric structure 351 between blocks 291 and 292 can separate block 291 from block 292.

Structure 355 of memory device 200 can be part of a barrier in the perimeter (e.g., boundary) of memory device 200. Only a portion of the barrier (that includes structure 355) is shown in FIG. A. The barrier can be located at the edges of a semiconductor die where memory device 200 is located. The barrier can be formed to surround the elements (e.g., memory cells and associated circuitry) of memory device 200 to protect the elements from factors (e.g., moisture, chemical, corrosion, and other factors) during processes of forming memory device 200.

In FIG. 3A, data lines 270₀ through 270_{N} are partially shown for simplicity. Data lines 270₀ through 270_{N} (associated with signals BL₀ through BL_{N}) of memory device 200 can be located over pillars 322 (shown in top view) of blocks 290-293 (with respect to the Z-direction). Data lines 270₀ through 270_{N} can have respective lengths extending in the X-direction. Data lines 270₀ through 270_{N} can extend over (e.g., on top of) and across (in the X-direction) blocks 290-293 and can be shared by blocks 290-293.

Region 345 of memory device 200 can be called a staircase region at which the control gates of a respective block have edges that form a staircase structure (e.g., staircase structure 304 shown in FIG. 3C). Region 345 can be part of memory device 200 where conductive contacts of memory device 200 can be formed. FIG. 3B and FIG. 3C show top view and side view, respectively, of some of the conductive contacts (e.g., conductive contacts 365_{SGS}, 365_{WL}, 365_{SGD0}, and 365_{SGDi}). In FIG. 3A, the conductive contacts in region 345 can provide electrical connections (e.g., signals) to respective select gates (e.g., select gates 280, 281₀ and 281ᵢ in FIG. 2) and control gates (e.g., control gates 250₀ through 250_{M} in FIG. 2) in respective blocks 290, 291, 292, and 293 of memory device 200. In FIG. 3A, region 345 can also include other structures (e.g., structures 344, structures 344′, and structure 355, described below). Portions labeled “3B” in FIG. 3A are shown in detail in FIG. 3B.

As shown in FIG. 3B, memory device 200 can include pillars 322 (shown in top view) in each of the blocks (e.g., block 290, 291, and 292). Pillars 322 are memory cell pillars, which are different from the pillars of structures 344 and 344′ of memory device 200. Pillars 322 are part of respective memory cell strings 230 (also schematically shown in FIG. 2) of memory device 200.

As shown in FIG. 3B, pillars (memory cell pillars) 322 can be located under (below) and coupled to respective data lines (only data lines 270_{N-1} and 270_{N} are shown). Memory cells 202 of a memory cell string can be located (e.g., can be formed vertically) long the length (shown in FIG. 3C) of a corresponding pillar 322. Pillars 322 of blocks 290-293 can share data lines 270₀ through 270_{N}.

As shown in FIG. 3A and FIG. 3B, data lines 270₀ through 270_{N} (associated with signals BL₀ through BL_{N}) of memory device 200 can be located over (above) pillars 322 (and over associated memory cell strings) in memory array 201. Data lines 270₀ through 270_{N} can be coupled to respective pillars 322 (which are located under data lines 270₀ through 270_{N} in the Z-direction).

As shown in FIG. 3B, structures 344 and structures 344′ can be adjacent dielectric structures 351 and adjacent respective conductive contacts 365_{WL}. For simplicity, only some of structures 344 and structures 344′ of memory device 200 are shown in FIG. 3B. Also for simplicity, only some of structures 344 and structures 344′ are labeled.

FIG. 3B shows example locations of structures 344 and structures 344. However, the locations of structures 344 and structures 344′ can be different from the locations shown in FIG. 3B. For example, some of structures 344′ can be located at the locations of structures 344. In another example, some of structures 344 can be located at the locations of structures 344′. FIG. 3F and FIG. 3G (described below) shows an example locations of structures 344 and structures 344′ that are different from the example shown in FIG. 3B.

As shown in FIG. 3B, conductive contacts 365_{SGS}, 365_{WL}, 365_{SGD0}, 365_{SGD1}, 365_{SGD2}, and 365_{SGDi} can have a circular shape (e.g., a circular cross-section viewed from a direction perpendicular to the X-Y plan). Structures 344 and structures 344′ can also have a circular shape (e.g., a circular cross-section viewed from a direction perpendicular to the X-Y plan).

Structures 344 can be called support structures (e.g., support pillars). The support structures (e.g., structures 344′) are formed to provide support (structural support) for part of memory device 200 (e.g., region 345) during fabrication of memory device 200. The support structures are electrically uncoupled to other elements (e.g., circuitry) of memory device 200.

Structures 344′ can also be called support structures (e.g., support pillars). However, unlike structure 344, structure 344′ can be formed to also provide electrical connections (e.g., to form part of respective conductive paths) between circuitry (e.g., circuitry 395 in FIG. 3C) of memory device 200 and other elements of memory device 200. For example, some of structures 344′ can be part of conductive paths (not shown) between circuitry 395 (FIG. 3C) and data lines 270₀ through 270_{N} and other elements of memory device 200.

As mentioned above, conductive contacts 365_{SGS}, 365_{WL}, 365_{SGD0}, 365_{SGD1}, 365_{SGD2}, and 365_{SGDi} in FIG. 3B can be formed to provide electrical connections (e.g., signals) to respective select gates (e.g., select gates 280, 281₀ and 281ᵢ in FIG. 2) and control gates (e.g., control gates 250₀ through 250_{M} of FIG. 2) of memory device 200.

As shown in FIG. 3B, memory device 200 can include conductive materials 340 that can form (e.g., can be materials included in) respective select gate (e.g., source select gate associated with signal SGS0) and the control gates (associated with signals WL₀ through WL_{M}) of block 291.

Memory device 200 can include conductive materials 340_{SGD0}, 340_{SGD1} and 340_{SGD2} and 340_{SGDi} in block 291 that can form (e.g., can be materials included in) respective select gates (e.g., drain select gates) of block 291. In FIG. 3B, conductive materials 340_{SGD0} and 340_{SGDi} can form two of the four respective drain select gates (e.g., drain select gates 280₀ and 280ᵢ in FIG. 2) of block 291. Conductive materials 340_{SGD1} and 340_{SGD2} in FIG. 3B can form the other two of the four drain select gates of block 291 (e.g., not shown in FIG. 2).

As shown in FIG. 3B, conductive materials 340_{SGD0}, 340_{SGD1}, 340_{SGD2}, and 340_{SGDi} (FIG. 3B) can be electrically separated from each other by a gap 347 (which can be filled with a dielectric material (or materials)). For simplicity, only one gap 347 is labeled in FIG. 3B.

As shown in FIG. 3B, like block 291, block 292 also include conductive materials 340 that are electrically separated (electrically and physically separated) from conductive materials 340 of block 291 by dielectric structure 351 between blocks 291 and 292. In block 292, conductive materials 340₀, 340₁, 340_{M-1}, and 340_{M} can form respective control gates (associated with signals WL′₀ through WL′_{M}) of block 292. Different portions (e.g., side views) of memory device 200 along lines 3C-3C, line 3D-3D, and line 3E-3E of FIG. 3B are shown in FIG. 3C, FIG. 3D, and FIG. 3E, respectively.

FIG. 3C shows a portion (e.g., a side view) in the Y-Z direction of memory device 200 along line 3C-3C of FIG. 3B. As shown in FIG. 3C, memory device 200 can include levels 362, 364, 366, 372, 374, 376, and 378 that are physical levels (e.g., layers) in the Z-direction of memory device 200. Conductive materials 340 can be located (e.g., stacked) one level (e.g., one layer) over another in respective levels 362, 364, 366, 372, 374, and 376.

Conductive materials 340_{SGD0}, 340 _{SGD1}, 340 _{SGD2}, and 340_{SGDi} can be located on the same level (e.g., level 378). Only two of conductive materials 340_{SGD0}, 340 _{SGD1}, 340 _{SGD2}, and 340_{SGDi} (conductive materials 340_{SGD0} and SGD_{SGDi}) are shown in FIG. 3C.

As shown in FIG. 3C, conductive materials 340 can interleave with dielectric materials (levels of dielectric materials) 341 in the Z-direction. Conductive materials 340 can include metal (e.g., tungsten or tungsten-based material), other conductive materials, or a combination of conductive materials. Dielectric materials 341 can include silicon dioxide.

Signals SGS, WL₀, WL₁, WL_{M-1}, WL_{M}, SGD₀, and SGDᵢ in FIG. 3C associated with respective conductive materials 340 are the same signals shown in FIG. 2. As shown in FIG. 3C, one of conductive materials 340 can form the select gate associated with signal SGS (e.g., source select gate 280 shown in FIG. 2). Other conductive materials 340 can form the control gates (e.g., the control gates associated with signals WL₀, WL₁, WL_{M-2}, WL_{M-1}, and WL_{M}) of memory device 200. Conductive material 340_{SDG0} and 340_{SGDi} can form the select gates associated with signals SGD₀, and SGDᵢ (e.g., drain select gates 281₀ and 281ᵢ, respectively, in FIG. 2).

FIG. 3C shows an example of memory device 200 including one level of conductive material 340 that forms form the select gate (e.g., source select gate) associated with signal SGS. However, multiple levels of conductive material 340 can be used to form multiple source select gates (in the Z-direction) of memory device 200.

FIG. 3C shows an example of memory device 200 including one level (e.g., level 378) of multiple drain select gates on the same level (formed by respective conductive materials 340_{SGD0} through SGDᵢ on level 378). However, memory device 200 can include multiple levels (similar to level 378) stacked one over another in the Z-direction, in which each of such multiple levels can include multiple drain select gates (e.g., four drain select gates in each of the multiple levels).

As shown in FIG. 3C, memory device 200 can include staircase structure 304 located in region (e.g., staircase region) 345. For simplicity, only a portion of staircase structure 304 is shown in FIG. 3C (e.g., a middle portion of staircase structure 304 is omitted from FIG. 3C). As shown in FIG. 3C, respective portions (e.g., end portions) of conductive materials 340 and their respective edges (e.g., steps (or risers)) 340E1, 340E2, 340E3, and 340E4) can collectively form staircase structure 304. As shown in FIG. 3C, dielectric materials 341 can also include edges (not labeled) adjacent (e.g., aligned in the Z-direction with) respective edges 340E1 through 340E4. Thus, staircase structure 304 can also be formed in part by portions and edges of dielectric materials 341.

FIG. 3C also shows tiers 350 of memory device 200. Each tier 350 can include a level of conductive material 340 and an adjacent level of dielectric material 341. As shown in FIG. 3C, tiers 350 can be located (e.g., stacked) one over another in the Z-direction over substrate 399. Each tier 350 can have respective memory cells 202 and associated control gates formed by a respective conductive materials 340. For example, FIG. 3C shows five tiers 350 of memory cells 202 and associated control gates included in five respective levels 364, 366, 372, 374, and 376. FIG. 3C shows a few tiers of memory device 200 for simplicity. However, memory device 200 can include up to hundreds of tiers (or more than hundreds of tiers).

Other blocks (e.g., blocks 290, 292, and 293 in FIG. 3B) of memory device 200 can also have their own tiers of memory cells 202 and respective control gates (e.g., respective word lines) associated with the tiers the memory cells, and staircase structures similar to staircase structure 304 in block 291 in FIG. 3C. For simplicity, details of staircase structures of the other blocks (e.g., blocks 290, 292, and 293) of memory device 200 are omitted from the description herein.

As shown in FIG. 3C, memory device 200 can include a base structure 390 and a structure (e.g., source structure) 398 adjacent (e.g., located over) base structure 390. Structure 398 can include multiple levels (e.g., multiple layers) of different materials stacked one over another over a base structure 390 of memory device 200. For example, structure 398 can include a material 387, a material 393, a material 394, and materials 381 and 383 that are stacked one over base structure 390 (which include substrate 399 and circuitry 395). Material 394 can include polysilicon (e.g., doped or undoped polysilicon). Each of materials 381, 383, and 387 can include a dielectric material (e.g., silicon dioxide). Material 393 can be included in a conductive region of structure 398. Material 393 can include conductively doped semiconductor materials or other conductive materials. Example materials of conductively doped semiconductor materials for material 393 include conductively doped polysilicon, conductively doped germanium, conductively doped silicon-germanium (SiGe), or other conductive materials.

As shown in FIG. 3C, structures 398 can be located between base structure 390 and the region of memory device 200 that include the interleaved levels of conductive materials 340 and dielectric materials 341. For example, as shown in FIG. 3C, structures 398 can be located between base structure 390 and the level of conductive material 340 that is closest to base structure 390 (e.g., conductive material 340 on level 362 associated with signal SGS).

As shown in FIG. 3C, base structure 390 can include substrate 399. Substrate 399 can include a semiconductor (e.g., silicon) substrate. Substrate 399 can also include circuitry 395. Circuitry 395 can include circuit elements (e.g., transistors Tr1 and Tr2 shown in FIG. 3C) coupled to other elements of memory device 200. The other elements can include data lines 270₀ through 270_{N} (shown in FIG. 3A); conductive contacts 365_{WL}, 365_{SGS}, and 365_{SGDi} (and conductive contacts 365_{SGD0}, 365 _{SGD1}, and 365_{SGD2} shown in FIG. 3B); conductive connections 392, conductive paths 391 and other (not shown) conductive connections; and other circuit elements of memory device 200. The circuit elements (e.g., transistors Tr1 and Tr2) of circuitry 395 can be configured to perform part of a function of memory device 200. For example, transistors Tr1 and Tr2 can be part of decoder circuits, driver circuits (e.g., word line drivers), buffers, sense amplifiers, charge pumps, and other circuitry of memory device 200.

As shown in FIG. 3C, conductive paths (e.g., conductive routings) 391 can include portions extending in the Z-direction (e.g., extending vertically). Conductive paths 391 can include (e.g., can be coupled to) at least some of the conductive contacts (e.g., conductive contacts 365_{WL}, 365_{SGS}, and 365_{SGDi}) and structures 344′. As shown in FIG. 3C, conductive paths 391 can be coupled to circuitry 395. For example, at least one of conductive paths 391 can be coupled to at least of one of transistors Tr1 and Tr2 of circuitry 395.

Conductive paths 391 and conductive connections 392 can provide electrical connections between elements of memory device 200. For example, conductive paths 391 can be coupled to conductive contacts 365_{WL}, 365_{SGS}, and 365_{SGDi}, and circuit elements (e.g., word line drivers and word line decoders, not shown) of circuitry 395 to provide electrical connections (e.g., in the form of signals SGS, WL₀, WL₁, WL_{M-1}, WL_{M}, and SGDᵢ) from circuit elements (e.g., word line drivers, word line decoders, and charge pumps, not shown) in circuitry 395 to conductive contacts 365_{WL}, 365_{SGS}, and 365_{SGDi}, respectively.

As shown in FIG. 3C, conductive contacts 365_{WL} and 365_{SGS} can include respective pillars (conductive pillars) 365P extending in the Z-direction (e.g., extending vertically). Conductive contacts 365_{WL} and 365_{SGS} (including a respective pillar) can contact (form an electrical connection with) respective conductive materials 340. Conductive contacts 365_{WL} can be part of conductive paths (e.g., part of conductive paths 391) to carry electrical signals to the control gates (e.g., control gates associated with signals WL₀ through WL_{M}) of memory device 200. Conductive contacts 365_{SGS} can be part of conductive paths (e.g., part of conductive paths 391) to carry electrical signals to the select gate (e.g., source select gate associated with signal SGS) of memory device 200.

As shown in FIG. 3C, a particular conductive contact (e.g., one of conductive contacts 365_{WL}) can contact (can be electrically in contact with) one of the conductive materials (e.g., only one of conductive materials on levels 362, 364, 366, 372, 374, and 376) among the conductive materials of memory device 200. For example, conductive contact 365_{WL} that contacts the control gate associated with signal WL_{M} can contact conductive material 340 on level 376 and electrically separated from the rest of the conductive materials 340 on levels 362, 364, 366, 372, and 374. As shown in FIG. 3C, conductive contact 365_{WL} that contacts the control gate associated with conductive material 340 on level 376 can extend through (go through and not make an electrical contact with) conductive materials 340 on levels 362, 364, 366, 372, and 374. In another example, conductive contact 365_{WL} that contacts the control gate associated with signal WL_{M-2} can contact conductive material 340 on level 372 electrically separated from (go through and not make an electrical contact with) conductive materials 340 on levels 362, 364, and 366, 374, and 376.

As shown in FIG. 3C, conductive contacts 365_{WL} and 365_{SGS} can extend into (e.g., partially extend into) structure 398. However, conductive contacts 365_{WL} and 365_{SGS} are electrically separated from structure 398.

As shown in FIG. 3C, structures 344 can include respective pillar structures 344P that can have lengths extending in the Z-direction (e.g., extending vertically). Structures 344 (including pillar structures 344P) can have the same length. Structures 344 can extend through (go through) conductive materials 340 and dielectric materials 341. Structures 344 (including pillar structures 344P) are electrically separated from (electrically unconnected to) conductive materials 340. As shown in FIG. 3C, structures 344 can extend into (e.g., partially extend into) structure 398. However, structures 344 are electrically separated from structure 398. As shown in FIG. 3C, structures 344 are not coupled to circuitry 395. As mentioned above in the description of FIG. 3B, structures 344 (not coupled to circuitry 395) are support structures (e.g., support pillars) to provide structural support to region 345 of memory device 200.

As shown in FIG. 3C, structures 344′ can include respective pillar structures 344′P that can have lengths extending in the Z-direction (e.g., extending vertically). Structures 344′ (including pillar structures 344′P) can have the same length. Structures 344′ can extend through (go through) conductive materials 340 and dielectric materials 341. Structures 344′ (including pillar structures 344′P) are electrically separated from (electrically unconnected to) conductive materials 340. As shown in FIG. 3C, structures 344′ can extend into (e.g., partially extend into) structure 398. However, structures 344 are electrically separated from (electrically unconnected to) structure 398. Structures 344′ can be coupled (electrically coupled) to circuitry 395 through respective conductive connections 392. For example, structures 344′ can be coupled (electrically coupled to) elements (e.g., transistors Tr1 and Tr2) of circuitry 395 through respective conductive connections 392. For simplicity, conductive connections 392 are symbolically shown in FIG. 3C as dashed lines. However, each conductive connection 392 can include a conductive structure that can include a conductive material (or a combination of conductive materials). Conductive connections 392 can be coupled to (or can be part of) conductive paths 391.

As shown in FIG. 3C, memory device 200 can include conductive connections 392 coupled to (e.g., coupled between) some of conductive contacts 365_{WL} and circuitry 395. However, in an alternative structure of memory device 200, conductive connections 392 coupled to conductive contacts 365_{WL} may be omitted (e.g., not formed).

As shown in FIG. 3C, pillar (memory pillar) 322 can include a conductive channel portion 325 along the length (in the Z-direction) of pillar 322. Pillar 322 can include a charge storage portion (not shown) to store information in associated memory cells located along the length of pillar 322. Conductive channel portion 325 can include a conductive polysilicon portion (e.g., conductively doped polysilicon portion). Pillar 322 can have an ONO (SiO₂, Si₃N₄, SiO₂, Si) structure, a TANOS (TaN, Al₂O₃, Si₃N₄, SiO₂, Si) structure (or a structure similar to a TANOS structure), a SONOS (Si, SiO₂, Si₃N₄, SiO₂, Si) structure, a floating-gate structure, or other memory cell structures.

As shown in FIG. 3C, pillar 322 can extend through conductive materials 340 and dielectric materials 341 of tiers 350. Pillar 322 can also extend (e.g., partially extend) into structure 398. At least a portion (e.g., conductive channel portion 325) of pillar 322 can also extend partially into the conductive region (extend partially into material 393) of structure 398. For example, pillar 322 can include a bottom portion (including part of conductive channel portion 325) that can extend at least partially into the conductive region (extend partially into material 393) of structure 398 and can be adjacent (e.g., can contact) material 393. Conductive channel portion 325 can be part of a conductive path between a respective data line (e.g., data line 270_{N} in FIG. 3C) and the conductive region (that includes material 393) to carry current (e.g., current between data line 270_{N} and the conductive region during an operation (e.g., read, write, or erase) of memory device 200.

As shown in FIG. 3C, memory device 200 can include structures 385 associated with respective conductive contact 365_{WL}, structures 344 and 344′, dielectric structure 351, and structure 355. Structures 385 can be located on the same level (with respect to the Z-direction) of memory device 200 such that structures 385 can include respective edges (e.g., bottom edges) on level 360 and respective edges (e.g., top edges) on level 361. Structures 385 can be located in (e.g., embedded in) structure (e.g., source structure) 398. Structures 385 can be located between base structure 390 and respective conductive contact 365_{WL} and structures 344 and 344′. As shown in FIG. 3C, structures 385 can also be located between base structure 390 and the region of memory device 200 that include the interleaved levels of conductive materials 340 and dielectric materials 341. For example, structures 385 can be located between base structure 390 and the level of conductive material 340 that is closest to base structure 390 (e.g., conductive material 340 on level 362 associated with signal SGS). Structures 385 can be called landing structures (or alternatively plug structures).

FIG. 3D shows a portion (e.g., a side view) in the X-Z direction of memory device 200 along line 3D-3D of FIG. 3B. FIG. 3E shows a portion (e.g., a side view) in the X-Z direction of memory device 200 along line 3E-3E of FIG. 3B. As shown in FIG. 3D, conductive contact 365_{WL} can include a dielectric liner 365L and a material (or materials) 365M. conductive contact 365_{WL} can include a dielectric liner 365L having a portion adjacent conductive materials 340 and dielectric materials 341, and a material (or materials) 365M adjacent dielectric liner 365L. Dielectric liner 365L can include a dielectric material (e.g., a single layer of dielectric material), a combination of different dielectric materials (e.g., multiple layers of different dielectric materials). Example materials for dielectric liner 365L includes silicon dioxide, silicon nitride, or other dielectric materials. Material 365M can include a conductive material or multiple different conductive materials. Example materials for material 365M include metal (e.g., tungsten), titanium nitrite and tungsten (TiN and W) or other conductive materials. FIG. 3D shows an example structure of liner 365L. FIG. 3K (described below) show another example structure of liner 365L.

As shown in FIG. 3D and FIG. 3E, structure 344 can include a dielectric liner 344L having a portion adjacent conductive materials 340 and dielectric materials 341, and a material (or materials) 344M adjacent dielectric liner 344L. Dielectric liner 344L can include a dielectric material (e.g., a single layer of dielectric material), a combination of different dielectric materials (e.g., multiple layers of different dielectric materials). Example materials for dielectric liner 344L includes silicon dioxide, silicon nitride, or other dielectric materials. Example materials for material 344M include dielectric materials, semiconductor materials (e.g., polysilicon), combination of dielectric materials and semiconductor materials, or other materials.

As shown in FIG. 3E, structure 344′ can include a dielectric liner 344′L having a portion adjacent conductive materials 340 and dielectric materials 341, and a material (or materials) 344′M adjacent dielectric liner 344′L. Dielectric liner 344′L can include a dielectric material (e.g., a single layer of dielectric material), a combination of different dielectric materials (e.g., multiple layers of different dielectric materials). Example materials for dielectric liner 344′L includes silicon dioxide, silicon nitride, or other dielectric materials. Material 344′M can include a conductive material or multiple different conductive materials. Example materials for material 344′M include metal (e.g., tungsten), titanium nitrite and tungsten (TiN and W) or other conductive materials. As shown in FIG. 3E, memory device 200 can include conductive portions (e.g., conductive vias) 392C coupled to respective structures 344′ through respective structures 385 associated with structures 344′. Structures 385 associated with particular structures 344′ can be between the particular structures 344′ and respective conductive portions 392C. As shown in FIG. 3E, conductive portions 392C can be part of conductive connections 392 that couple respective structures 344′ to circuitry 395 of memory device 200. Although not shown in FIG. 3D, memory device 200 can also include conductive portions like conductive portions 392C coupled to (e.g., coupled between) conductive contacts 365_{WL} (FIG. 3D) and circuitry 395.

As shown in FIG. 3E, memory device 200 can include a conductive portion (e.g., conductive vias) 355C coupled to structure 355. Conductive portion 355C can be formed when conductive portions 392C are formed. However, unlike portions 392C, portion 355C are not electrically coupled to other elements (e.g., circuitry 395) of memory device 200.

As shown in FIG. 3D and FIG. 3E, structure 351 can include a dielectric liner 351L having a portion adjacent conductive materials 340 and dielectric materials 341, and a material (or materials) 351M adjacent dielectric liner 351L. Dielectric liner 351L can include a dielectric material (e.g., a single layer of dielectric material), a combination of different dielectric materials (e.g., multiple layers of different dielectric materials). Example materials for dielectric liner 351L includes silicon dioxide, silicon nitride, or other dielectric materials. Example materials for material 351M include dielectric materials, semiconductor materials (e.g., polysilicon), or combination of dielectric materials and semiconductor materials.

As shown in FIG. 3D and FIG. 3E, structure 355 can include a dielectric liner 355L having a portion adjacent conductive materials 340 and dielectric materials 341, and a material (or materials) 355M adjacent dielectric liner 355L. The materials of dielectric liner 355L and material 355M can be similar to (or the same as) the materials dielectric liner 344′L and material 344′M, respectively.

FIG. 3D and FIG. 3E shows example where conductive contact 365_{WL} and structures 344 and 344′, dielectric structure 351, and structure 355 may have respective voids 385V. Void 385V can be an empty space that is unoccupied by respective materials 365M, 344M, 344′M, 351′M, and 355′M of conductive contact 365_{WL} and structures 344 and 344′, dielectric structure 351, and structure 355. In an alternative structure of memory device 200, one or more of conductive contact 365_{WL} and structures 344 and 344′, dielectric structure 351, and structure 355 may not have respective voids 385V.

As shown in FIG. 3D and FIG. 3E, each structure (e.g., landing structure) 385 can include a liner (e.g., dielectric liner) 385L adjacent the materials of structure 398. Liner 385L can include a dielectric material, a combination of different dielectric materials (e.g., multiple layers of different dielectric materials). As an example, liner 385L can include a single dielectric material (e.g., a single layer of silicon dioxide). In another example, liner 385L can include two or more different dielectric materials (e.g., two different layers of dielectric materials adjacent each other). As an example, liner 385L can include silicon dioxide (e.g., a layer of silicon dioxide) adjacent an additional material (e.g., a layer of an additional material). The additional material can include silicon nitrite, carbon nitride, other materials.

FIG. 3D and FIG. 3E show and example where dielectric liners 365L, 344L, 344′L, 352L, and 355L can include respective portions (liner portions) between levels 360 and 361 and adjacent respective liners 385L of structures (e.g., landing structures) 385. In this example, the portions of dielectric liners 365L, 344L, 344′L, 352L, and 355L between levels 360 and 361 can be considered part of respective liners 385L of structures 385.

FIG. 3D and FIG. 3E show and example where conductive contact 365_{WL} and structures 344 and 344′, dielectric structure 351, and structure 355 can include portions of respective materials 365M, 344M, 344′M, 351M, and 355M between levels 360 and 361. In this example, portions of respective materials 365M, 344M, 344′M, 351M, and 355M between levels 360 and 361 can be considered part of structures 385.

In an alternative structure (not shown) of memory device 200, one or more of dielectric liners 365L, 344L, 344′L, 352L, and 355L may not have respective portions (liner portions) between levels 360 and 361. Thus, in the alternative structure, liners 385L can be adjacent (e.g., directly contacting) respective materials 365M, 344M, 344′M, 351M, and 355M between levels 360 and 361.

FIG. 3F and FIG. 3G shows an alternative structure of memory device 200 including a region 346 (FIG. 3F) and the locations of structures 344 and structures 344′ in region 346. FIG. 3F and FIG. 3G show the portions (e.g., top view and side view) of memory device 200 similar to those of FIG. 3B and FIG. 3E. Thus, similar (or the same) elements of memory device 200 shown in FIG. 3B, FIG. 3E, FIG. 3F, and FIG. 3G are not repeated.

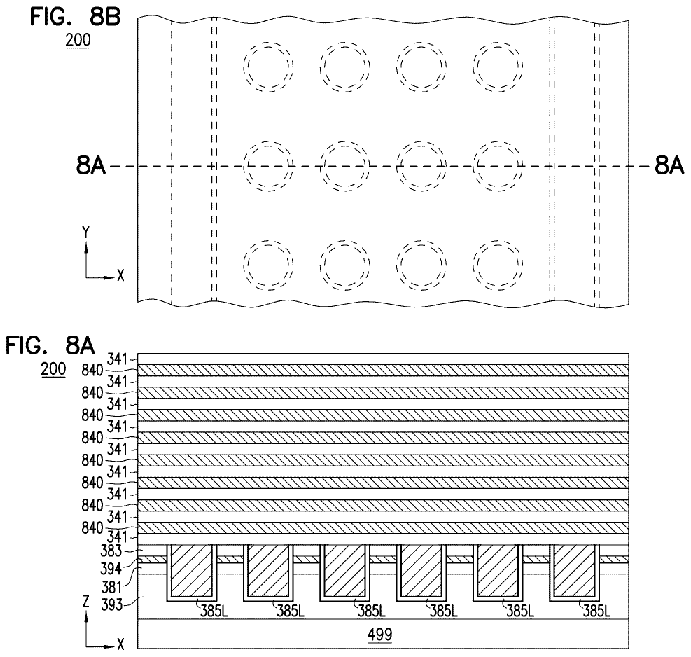

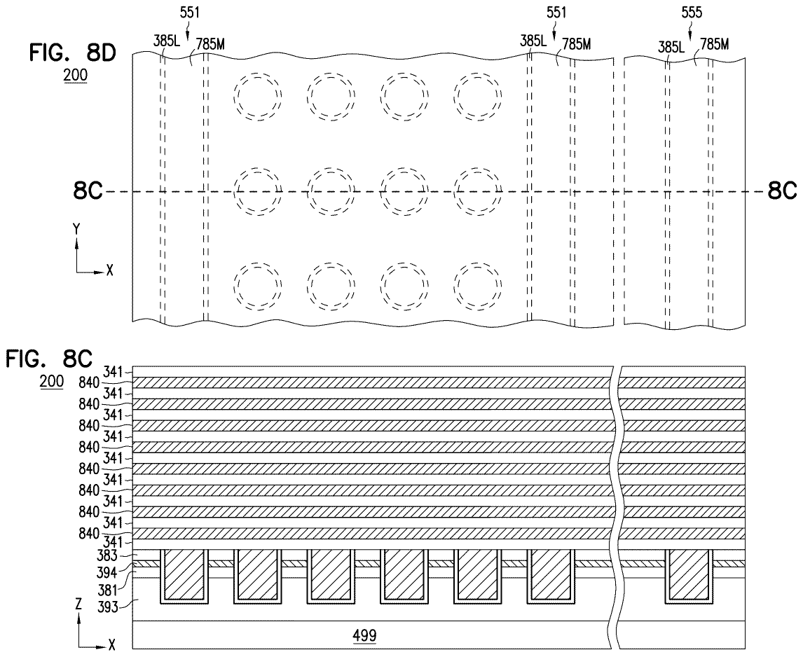

Differences between FIG. 3B and FIG. 3F include the absence of dielectric structures 351 in FIG. 3F. For example, in FIG. 3F, dielectric structures 351 may not be formed in region 346 of memory device 200 of FIG. 3F. In FIG. 3G, dielectric materials (e.g., silicon nitride) 840 are different from conductive materials of memory device of FIG. 3E. Dielectric materials 840 can be the same as dielectric material 840 formed in the process associated with FIG. 8D (described below) during the process of forming memory device 200.

FIG. 3H, FIG. 3I, and FIG. 3J shows an alternative structure of memory device 200 of FIG. 3C, FIG. 3D, and FIG. 3E, respectively, according to some embodiments described herein. As shown in FIG. 3H, FIG. 3I, and FIG. 3J, structures 385 associated with structures 344 can include materials 785. Examples for material 785 include tungsten, titanium nitride and tungsten (TiN and W), aluminum oxide, or other materials different from the materials of liners 385L. As a comparison, materials 785 can be omitted (not present) in memory device 200 of FIG. 3C, FIG. 3D, and FIG. 3E.

FIG. 3K shows an alternative liner 365L of conductive contact 365_{WL} of FIG. 3C and FIG. 3D, according to some embodiments described herein. As shown in FIG. 3K, liner 365L can include portions (e.g., recess portions) 365R adjacent levels of conductive materials 340. In some structures of memory device 200 of FIG. 3C and FIG. 3D, one or more of dielectric liners 351L, 344L, 344′L, and 355L can also have a dielectric liner like dielectric liner 365L of FIG. 3K.

FIG. 3L, FIG. 3M, and FIG. 3N shows conductive contact 365_{WL} and structures 344 and 344′ and corresponding widths and thickness, according to some embodiments described herein. Conductive contact 365_{WL} and structures 344 and 344′ are the same those shown in FIG. 3D and FIG. 3E.

As shown in FIG. 3L, each level of conductive material 340 can have a thickness (in the Z-direction) T1. Structure 385 can have a thickness T2. Thickness T2 can be measure from one edge (e.g., bottom edge) of structure 385 on level 360 to another edge (e.g., top edge) of structure 385 on level 361. Thickness T2 is greater than thickness T1. As shown in FIG. 3L, conductive contact 365_{WL} can include portions having respective widths W1 and W2 in the X-direction. The portion associated with width W1 is between the portion associated with width W2 and structure 385 associated with conductive contact 365_{WL}. Structure 385 associated with conductive contact 365_{WL} can have a width W3 the X-direction. Width W2 is greater than width W1. Width W3 is greater than width W1.

In FIG. 3M, thicknesses T1 and T2 are similar to (or the same as) thicknesses T1 and T2, respectively, of FIG. 3L. As shown in FIG. 3M, structure 344 can include portions having respective widths W4 and W5 in the X-direction. The portion associated with width W4 is between the portion associated with width W5 and structure 385 associated with structure 344. Structure 385 associated with structure 344 can have a width W6 the X-direction. Width W5 is greater than width W3. Width W6 is greater than width W3.

In FIG. 3N, thicknesses T1 and T2 are similar to (or the same as) thicknesses T1 and T2, respectively, of FIG. 3L. As shown in FIG. 3N, structure 344′ can include portions having respective widths W7 and W8 in the X-direction. The portion associated with width W7 is between the portion associated with width W8 and structure 385 associated with structure 344′. Structure 385 associated with structure 344′ can have a width W9 the X-direction. Width W8 is greater than width W6. Width W9 is greater than width W6.

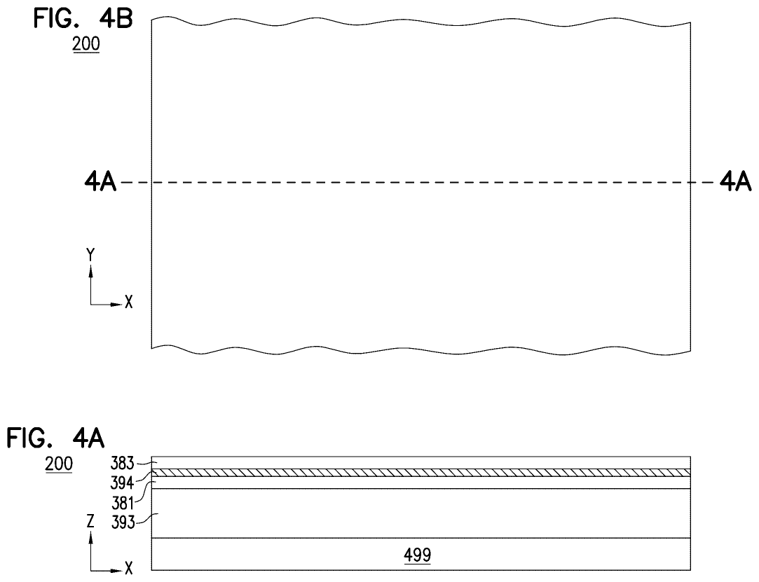

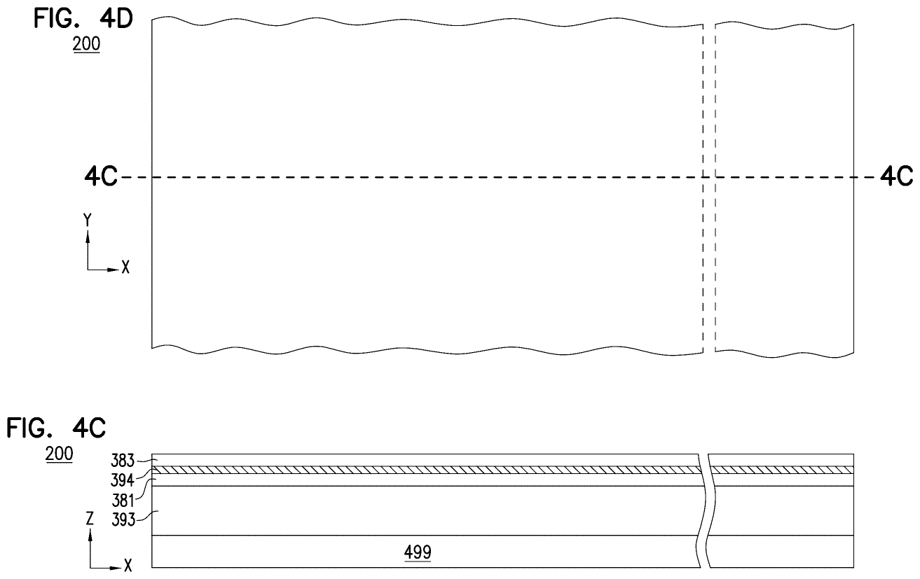

FIG. 4A through FIG. 16B show different views of structures during processes of forming memory device 200 of FIG. 2 through FIG. 3E, according to some embodiments described herein. In FIG. 2 through FIG. 16B, the same materials and elements are given the same reference labels, and their detailed descriptions may not be repeated in the description of FIG. 4A through FIG. 16B.

For simplicity, the processes associated with FIG. 4A through FIG. 16B involve formation of structures of part of a block (e.g., block 291 in FIG. 3B) of memory device 200. The structures of the other blocks (e.g., block 290, 292, and 293 in FIG. 3A) of memory device 200 can be formed using similar (or the same) processes described below with reference to FIG. 4A through FIG. 16B.

FIG. 4A shows a side view (e.g., a cross-section) of memory device 200 taken along line 4A-4A of FIG. 4B. FIG. 4B shows a top view of memory device 200. FIG. 4C shows another side view (e.g., a cross-section) of memory device 200 taken along line 4C-4C of FIG. 4D. FIG. 4D shows a top view of memory device 200. Lines 4A-4A and line 4C-4C are the same as line 3D-3D and line 3E-3E, respectively, of FIG. 3B, such that FIG. 4A and FIG. 4C (side views) show the same views of memory device 200 as FIG. 3D and FIG. 3E, respectively.

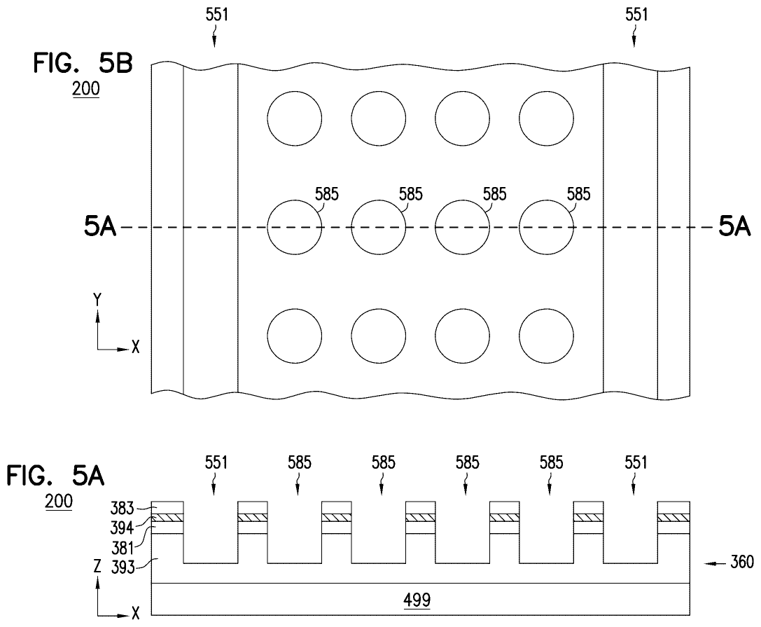

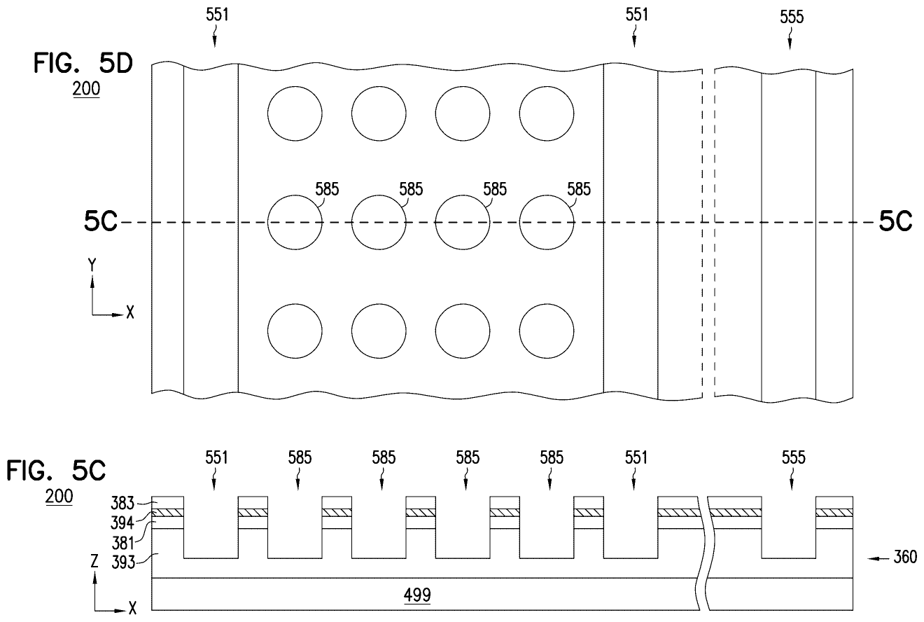

The views of memory device 200 shown in FIG. 5A, FIG. 5B, FIG. 5C, and FIG. 5D the same pattern of views of FIG. 4A, FIG. 4B, FIG. 4C, and FIG. 4D, respectively. For simplicity, the names of the views (e.g., side view and top view) are not repeated in FIG. 5A through FIG. 16B.

FIG. 4A, FIG. 4B, FIG. 4C, and FIG. 4D show memory device 200 after levels of materials (e.g., layers of materials) are formed over a structure 499. Structure 499 can include a semiconductor structure (e.g., silicon). As shown in FIG. 4A and FIG. 4C, the levels of materials formed over structure 499 can include materials 393, 381, 394, and 383. As described above with reference to FIG. 3C, materials 393 and 394 can include polysilicon. Materials 381 and 383 can include dielectric materials (e.g., silicon dioxide). In FIG. 4A and FIG. 4C, materials 393, 381, 394, and 383 can be sequentially formed one material after another over structure 499. For example, material 393 can be formed first over structure 499 and conductive material 383 can be formed last.

FIG. 5A, FIG. 5B, FIG. 5C, and FIG. 5D show memory device 200 after trenches (e.g., slits) 551 and 555 (FIG. 5C and FIG. 5D) and openings (e.g., holes) 585 are formed in materials 383, 394, 381, and 393. Forming trenches 551 and 555 and openings 585 can include removing (e.g., etching) a portion of each in materials 383, 394, 381, and 393 at the locations of trenches 551 and 555 and openings 585. As shown in FIG. 5A and FIG. 5C, trenches 551 and 555 and openings (e.g., holes) 585 can have similar (or the same) bottom (e.g., depth) at level 360 (which corresponds to level 360 of FIG. 3D and FIG. 3E.

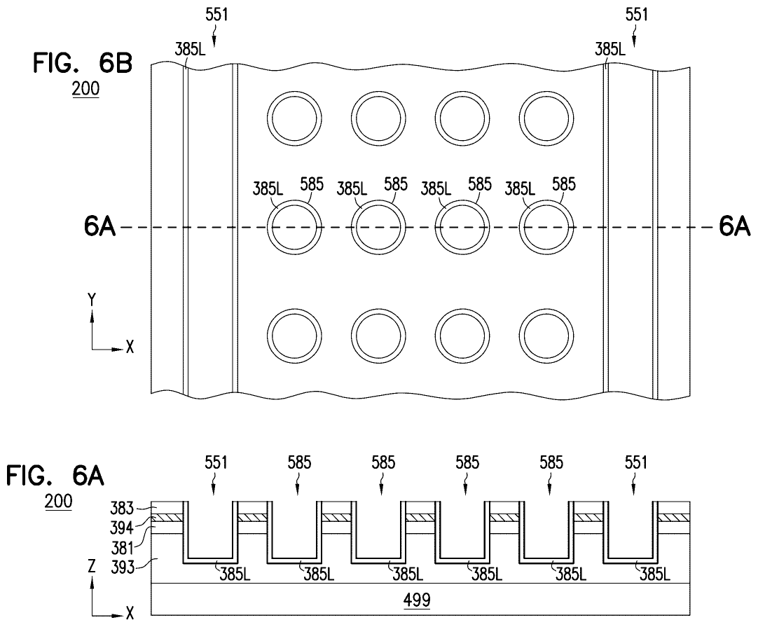

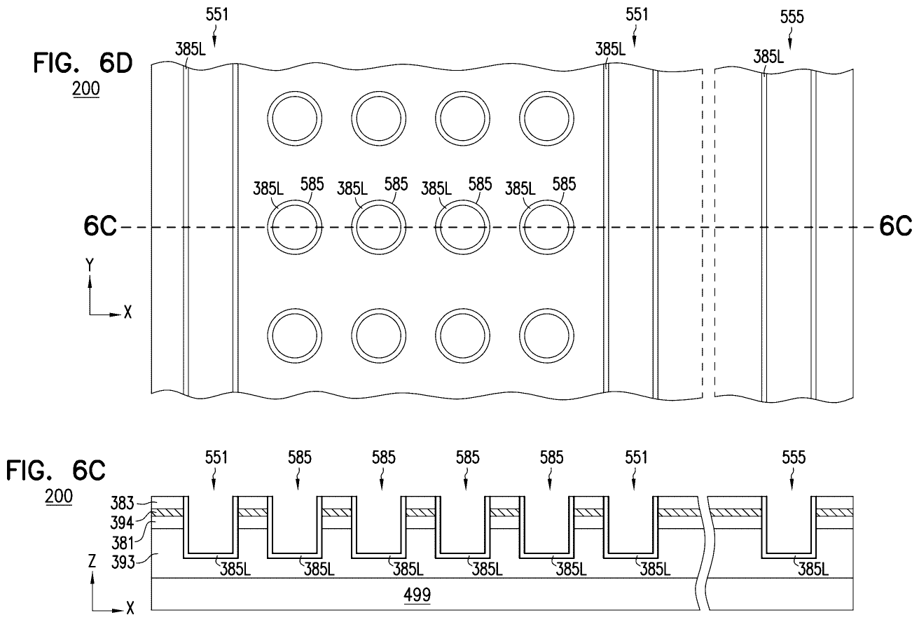

FIG. 6A, FIG. 6B, FIG. 6C, and FIG. 6D show memory device 200 after liners 385L are formed in respective trenches 551 and 555 (FIG. 6C and FIG. 6D) and openings 585. As shown in FIG. 6A and FIG. 6C, each liner 385L can be a relatively thin layer of material (or materials) formed in respective trenches 551 and 555 and openings 585.

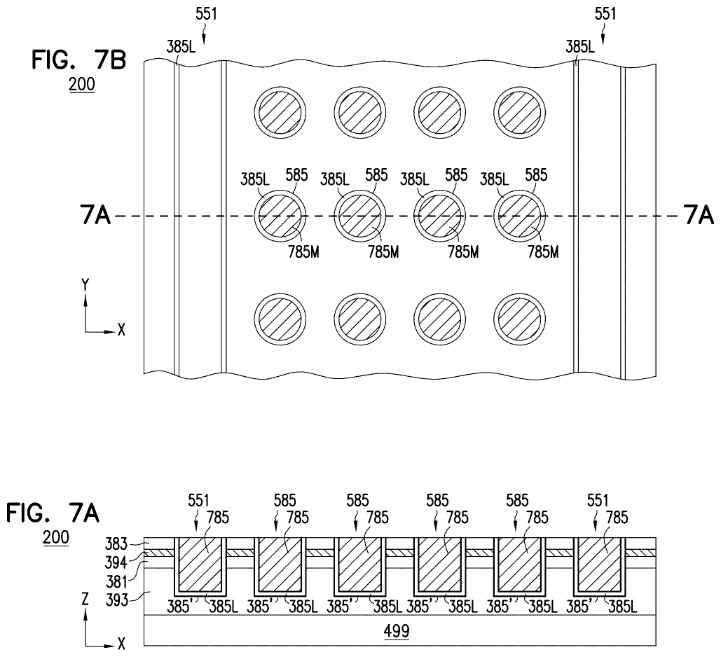

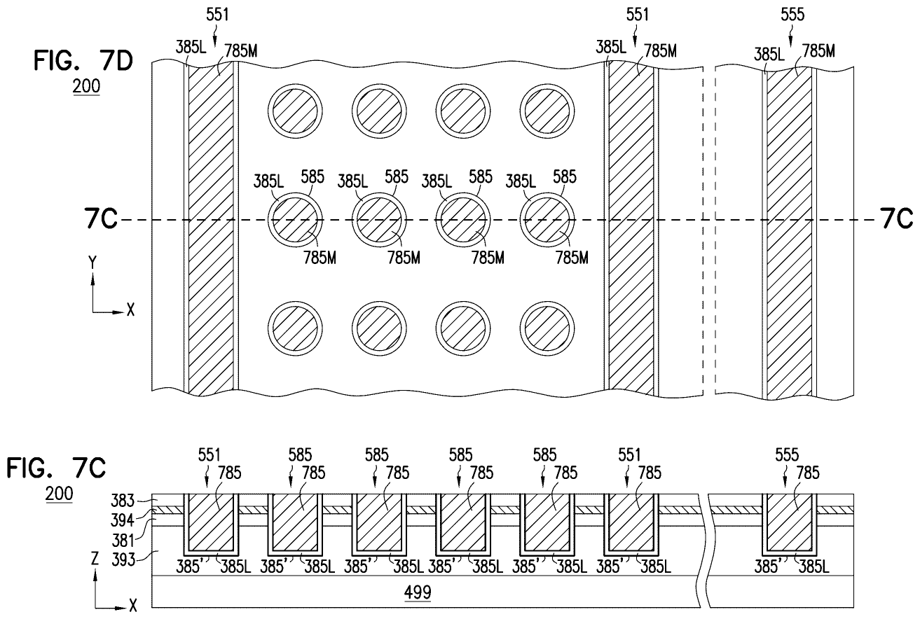

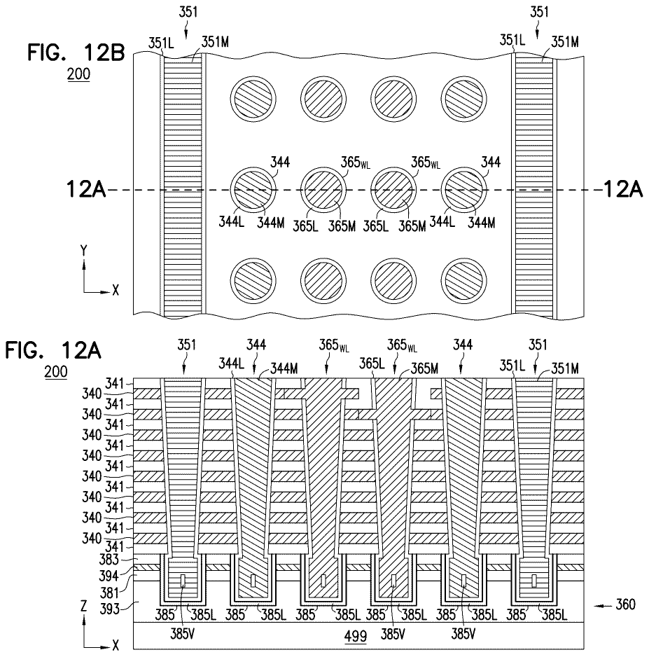

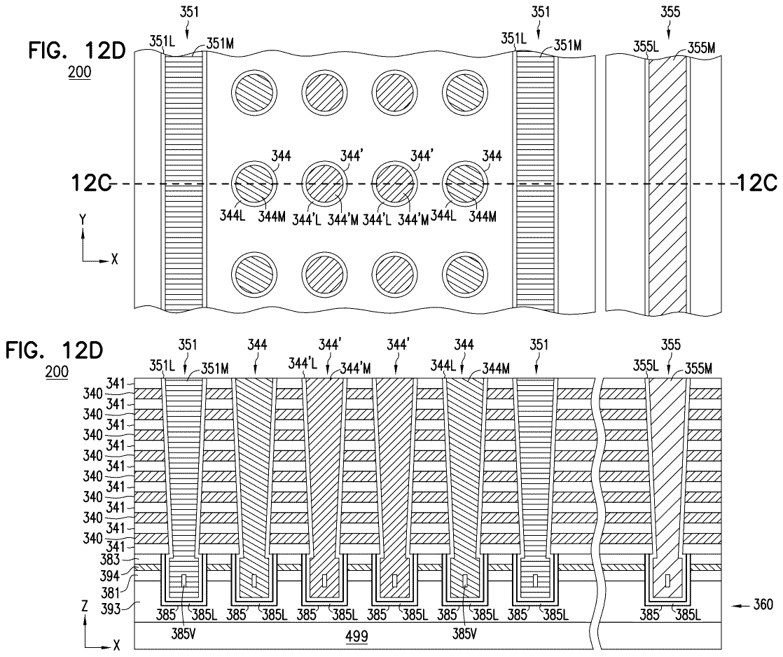

FIG. 7A, FIG. 7B, FIG. 7C, and FIG. 7D show memory device 200 after material 785 is on formed (e.g., filled) in trenches 551 and 555 (FIG. 7C and FIG. 7D) and openings 585 adjacent (e.g., over) liners 385L. Materials 785 are different from the materials of liners 385L. As described above (e.g., with reference to FIGS. 3I and 3J), examples for material 785 include tungsten, titanium nitride and tungsten (TiN and W), aluminum oxide, or other materials that are different from the materials of liners 385L. In FIG. 7A and FIG. 7C, materials 785 and liners 385L can form respective structures 385′. Structures 385′ can be called landing structures. In subsequent processes (e.g., FIG. 12A and FIG. 12C) of forming memory device 200, part of structures 385′ (e.g., liners 385L) become part of structures 385 (FIG. 12A and FIG. 12C). In part of memory device 200 (e.g., in region 346 in FIG. 3F) trenches 551 and associated structures 385′ may not be formed.

FIG. 8A, FIG. 8B, FIG. 8C, and FIG. 8D show memory device 200 after levels of dielectric materials 341 and levels of dielectric materials 840 are formed over other materials and over materials 785 in trenches 551 and 555 (FIG. 8D) and openings 585 (labeled in FIG. 7A, FIG. 7B, FIG. 7C, and FIG. 7D). Dielectric materials 341 and dielectric materials 840 can be sequentially formed one material after another, such that dielectric materials 341 and dielectric materials 840 can be interleaved with each other in different levels (in the Z-direction) of memory device 200 as shown in FIG. 8A and FIG. 8C. Dielectric materials 341 can include respective levels of silicon dioxide. Dielectric materials 840 can include respective levels of silicon nitride. In subsequent processes, dielectric materials (e.g., silicon nitride) 840 can be removed (e.g., exhumed) and replaced with respective levels of conductive material (e.g., tungsten or tungsten-based material or other conductive materials) to form respective control gates of memory device 200. Dielectric materials (e.g., silicon dioxide) 341 correspond to dielectric materials 341 of memory device 200 shown in FIG. 3C, FIG. 3D, and FIG. 3E. Dielectric materials 341 can be formed to provide separation between the control gates (e.g., the control gates associated with signals WL₀ through WL_{M} in FIG. 3C) of memory device 200.

In part of memory device 200 (e.g., in region 346 in FIG. 3F), dielectric materials 840 may not be replaced with conductive materials (like conductive materials 340 in FIG. 12A and FIG. 12B). Thus, in part of memory device 200 (e.g., in region 346 in FIG. 3F), dielectric materials 840 in that part of memory device 200 may remain in memory device 200 (e.g., remain in region 346 of memory device 200 in FIG. 3F).

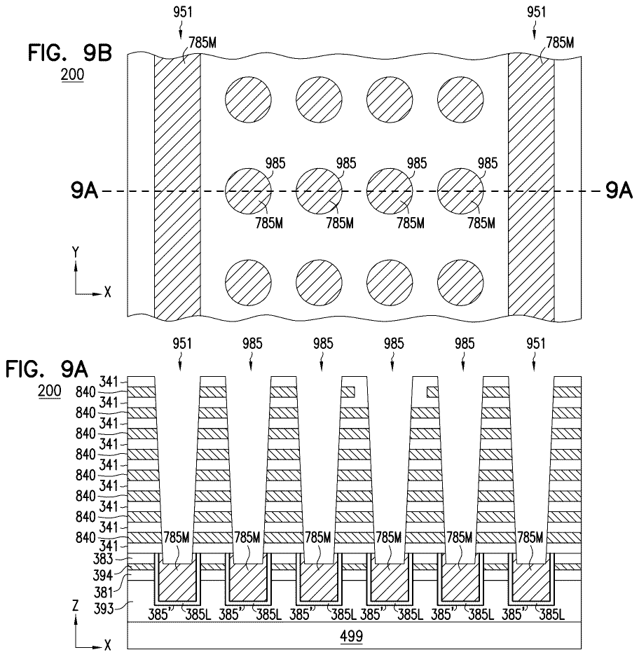

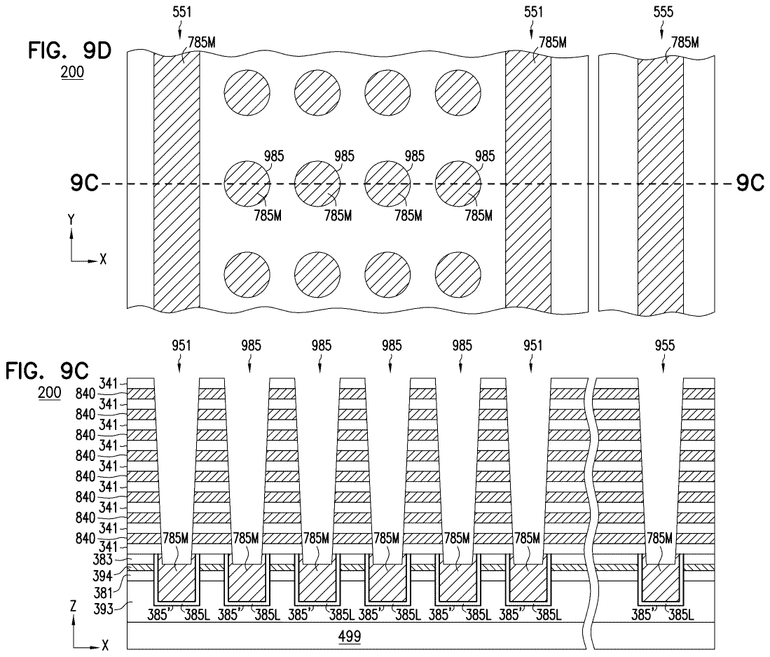

FIG. 9A, FIG. 9B, FIG. 9C, and FIG. 9D show memory device 200 after trenches 951 and 955 (FIG. 9C and FIG. 9D) and openings (e.g., hole) 985 are formed in dielectric materials 341 and dielectric materials 840. Trenches 951 and 955 and openings can be formed in respective portions of dielectric materials 341 and dielectric materials 840 over the locations of structures 385′. Trenches 951 and 955 and openings 585 can be formed such that materials 785 of structures 385′ can be exposed at trenches 551 and 555 and openings 585.

As shown in FIG. 9A, some portions of dielectric materials 840 (e.g., a top level of dielectric materials 840 in FIG. 9A) of can be patterned to prepare for contact locations of control gates that are subsequent formed in the locations of dielectric materials 840.

In FIG. 9A and FIG. 9C, forming trenches 951 and 955 and openings 985 can include removing (e.g., patterning and etching) a portion of dielectric materials 341 and dielectric materials 840 at the location of trenches 951 and 955 and openings 585 over structures 385′. Removing (e.g., patterning and etching) a portion of dielectric materials 341 and dielectric materials 840 can stop at structures 385′ (e.g., stop at materials 785). Thus, structures 385′ can provide landing structures (e.g., etch-stop structures) for formation of trenches 951 and 955 and openings 585. Using structures 385′ as landing structures can prevent potential over-etching of dielectric materials 341 and dielectric materials 840 at trenches 951 and 955 and openings 585. This allows of trenches 951 and 955 and openings 585 to be formed at a depth (e.g., intended depth). This can lead to improved structures of dielectric structure 351, structure 355, conductive contact 365_{WL}, and structures 344 and 344′ that are subsequently formed (FIG. 12A and FIG. 12B) in respective trenches 951 and 955 and openings 585, as described below.

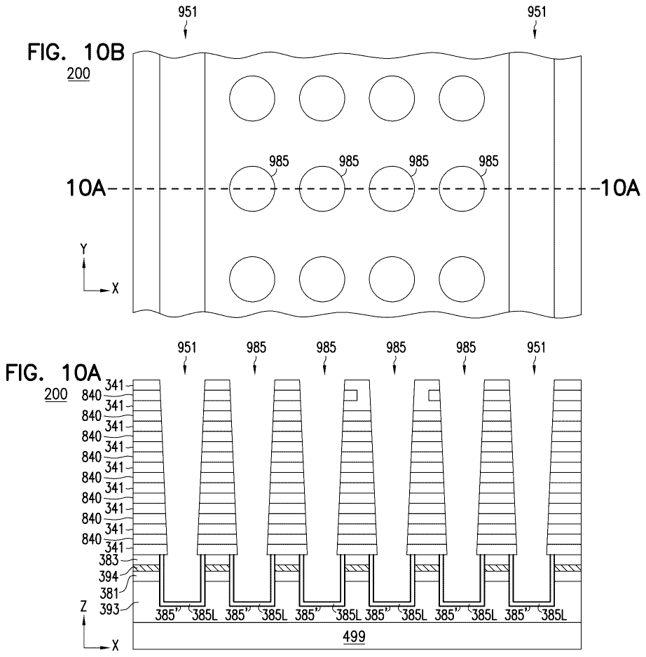

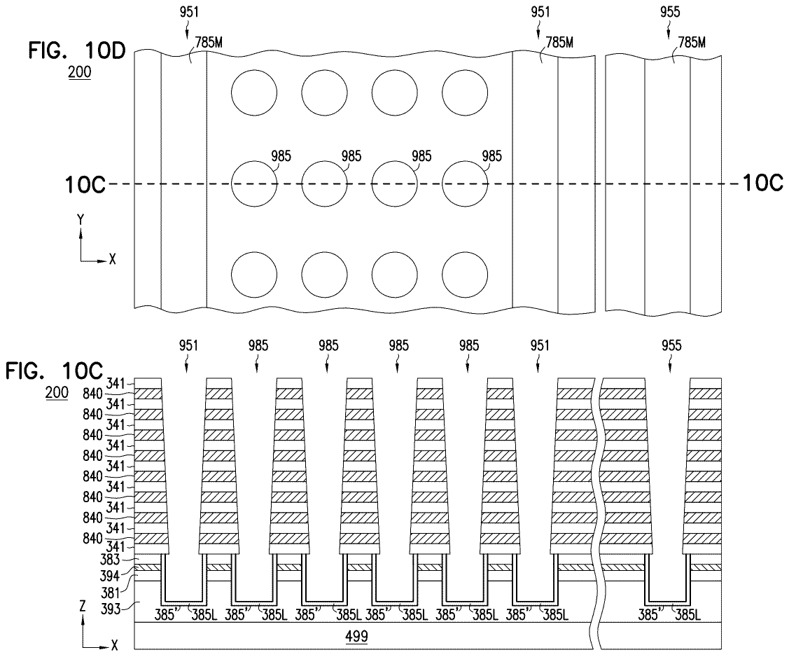

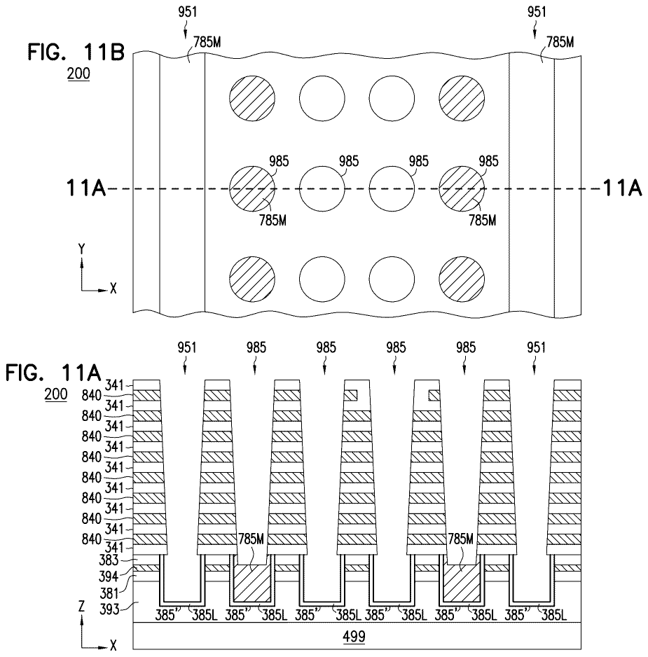

FIG. 10A, FIG. 10B, FIG. 10C, and FIG. 10D show memory device 200 after materials 785 (FIG. 9A and FIG. 9C) that are exposed at trenches 951 and 955 (FIG. 10C and FIG. 10D) and openings 985 are removed (e.g., exhumed). In alternative processes of forming memory device 200, materials 785 in some of structures 385′ may remain (not to be removed).

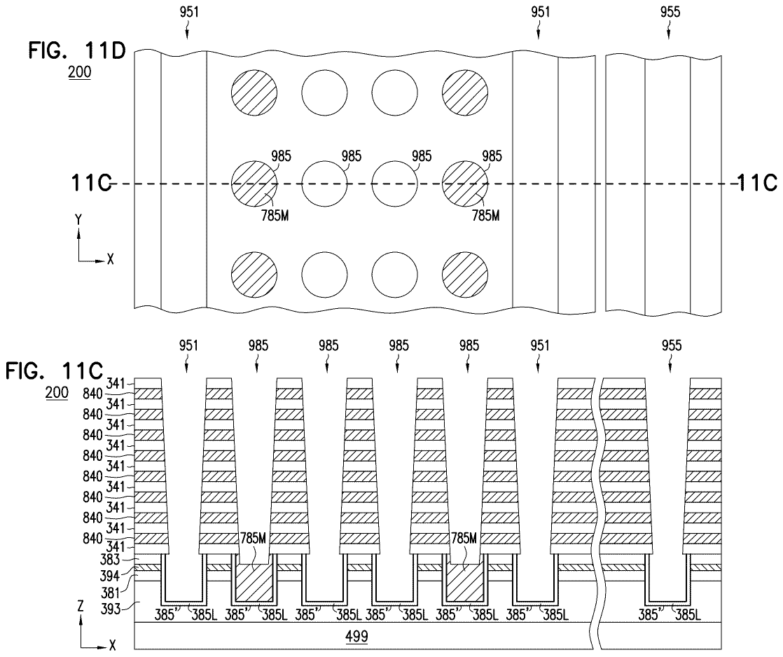

FIG. 11A, FIG. 11B, FIG. 11C, and FIG. 11D show memory device 200 in alternative processes in which materials 785 in structures 385′ associated with openings 585 may remain.

FIG. 12A, FIG. 12B, FIG. 12C, and FIG. 12D show memory device 200 after additional processes are performed on memory device 200 of FIG. 10A, FIG. 10B, FIG. 10C, and FIG. 10D. As shown in FIG. 12A and FIG. 12C conductive materials 340 are formed in the locations of dielectric materials 840. Forming conductive materials 340 can include removing (e.g., exhuming) dielectric materials 840 (FIG. 10A and FIG. 10C) then forming (e.g., depositing) conductive materials 340 in the locations of dielectric materials 840 (that were removed).

Forming conductive contact 365_{WL}, structures 344 and 344′, dielectric structure 351, and structure 355 can include forming dielectric liners 365L, 344L, 344′L, 351L, and 355L of respective conductive contact 365_{WL}, structures 344 and 344′, dielectric structure 351, and structure 355. Then, materials 365M, 344M, 344′M, 351M, and 355M of respective of conductive contact 365_{WL}, structures 344 and 344′, dielectric structure 351, and structure 355 can be formed adjacent respective dielectric liners 365L, 344L, 344′L, 351L, and 355L.

As shown in FIG. 12A and FIG. 12C, conductive contact 365_{WL}, structures 344 and 344′, dielectric structure 351, and structure 355 are formed in respective openings 985 and trenches 951 and 955 (labeled in FIG. 11A, FIG. 11B, FIG. 11C and FIG. 11D). Structures 385 associated with conductive contact 365_{WL}, structures 344 and 344′, dielectric structure 351, and structure 355 are also formed. Structures 385 can include part of (e.g., liners 385L) structures 385′ (FIG. 10A and FIG. 10B).

Liners 385L of structures 385 are formed (formed in FIG. 6A, FIG. 6B, FIG. 6C, and FIG. 6D) before conductive contact 365_{WL}, structures 344 and 344′, dielectric structure 351, and structure 355 are formed. Thus, in FIG. 12A and FIG. 12C, materials 365M, 344M, 344′M, 351M, and 355M of respective of conductive contact 365_{WL}, structures 344 and 344′, dielectric structure 351, and structure 355 can be formed (e.g., deposited) at a uniform depth (e.g., at the same level 360) defined by part of structures 385 (e.g., by liners 385L).

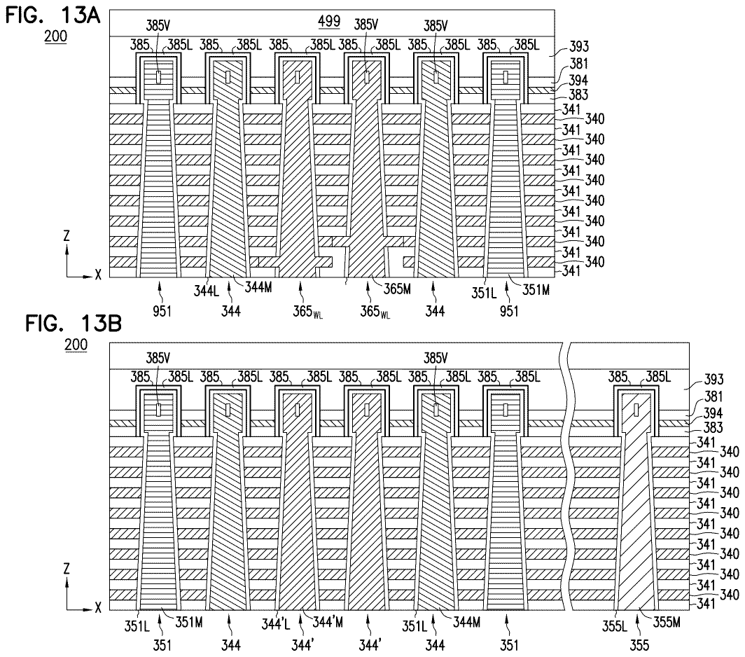

FIG. 13A and FIG. 13B shows memory device 200 of FIG. 12A and FIG. 12C after memory device 200 is rotated (flipped over) 180 degrees in the X-direction.

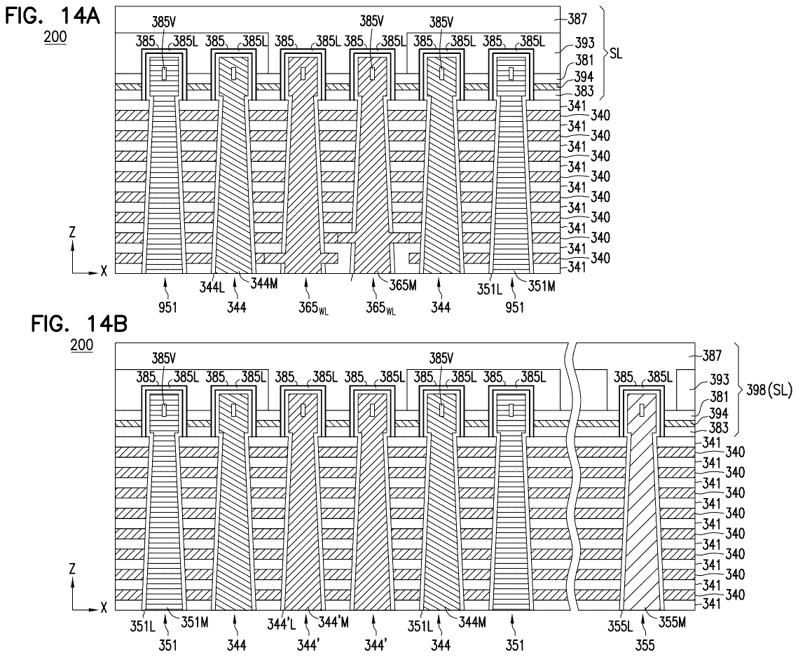

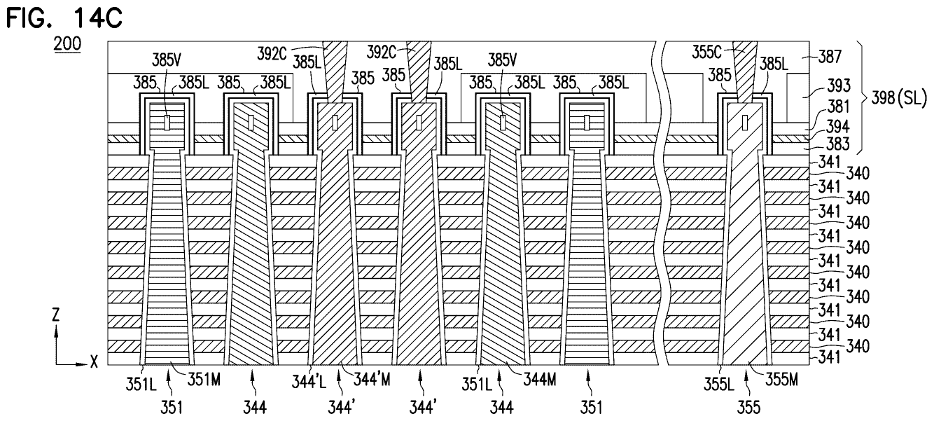

FIG. 14A and FIG. 14B show memory device 200 after structure (e.g., source structure) 398 (FIG. 14B) is formed. Forming structure (e.g., source structure) 398 can include removing structure 499 of FIG. 13A and FIG. 13B and removing part of material 393. Then, material (e.g., silicon dioxide) 387 can be formed adjacent other materials and liners 385L as shown in FIG. 14A and FIG. 14B.

FIG. 14C shows memory device 200 of FIG. 14B after conductive portions 392C and 355C associated with structures 344′ and structure 355 are formed. Forming conductive portions 392C and 355C can include forming openings (e.g., holes, not shown) in materials 387, and forming (e.g., depositing conductive materials) conductive portions 392C and 355C in the openings in materials 387.

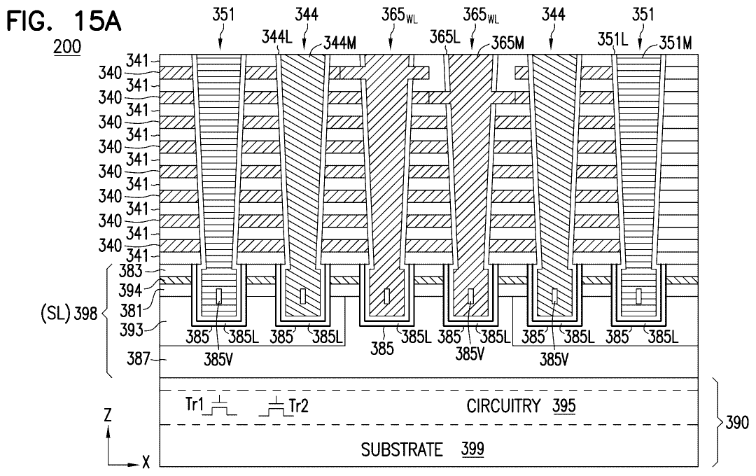

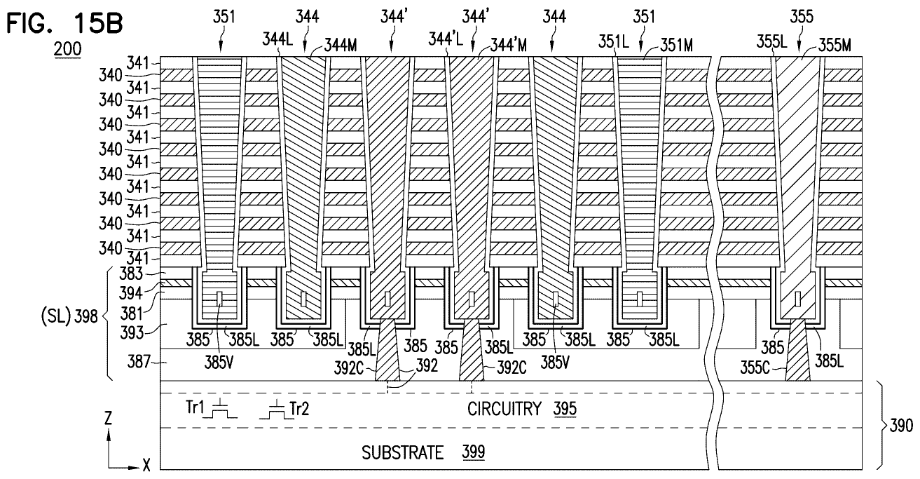

FIG. 15A and FIG. 15B show memory device 200 of FIG. 14A and FIG. 14C after base structure 390 is formed adjacent structure (e.g., source structure) 398. FIG. 15A and FIG. 15B also show memory device 200 after it is rotated (flipped over) 180 degrees in the X-direction. In FIG. 15A and FIG. 15B, memory device 200 can be rotated 180 degrees after (or before) base structure 390 is formed. As shown in FIG. 15A and FIG. 15B, base structure 390 can include circuitry 395 formed in (or formed on) substrate 399. Base structure 390 is described above with reference to FIG. 3C.

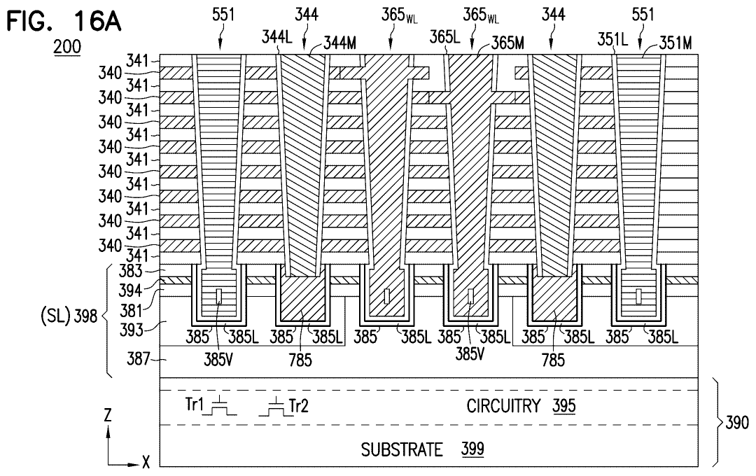

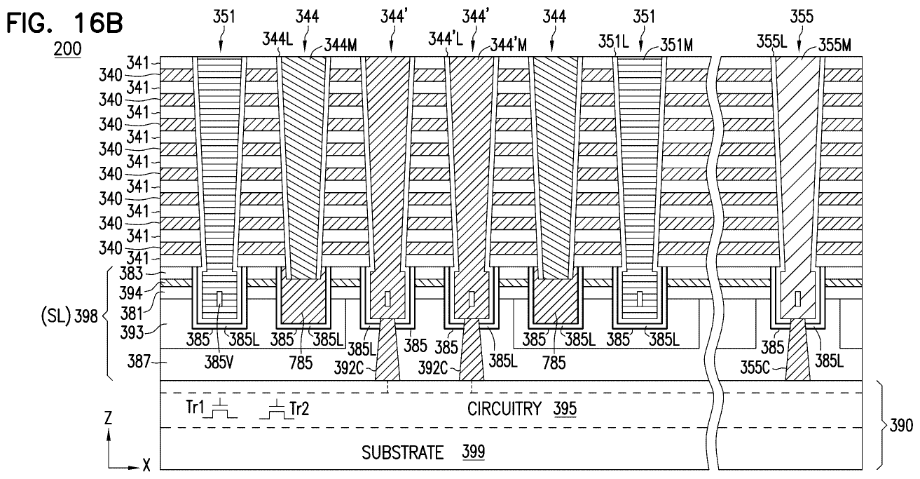

FIG. 16A and FIG. 16B show an alternative structure memory device 200 based on alternative processes described above with reference to FIG. 11A, FIG. 11B, FIG. 11C, and FIG. 11D. As shown in FIG. 16A and FIG. 16B, materials 758 remain in structures 385 associated with structures 344.

The processes of forming memory device 200 described above with reference to FIG. 4A through FIG. 16B can include other processes to form a complete memory device (e.g., memory device 200). Such processes are omitted from the above description so as not to obscure the subject matter described herein.

Memory device 200 as described allows it to have improvements and benefits in comparison with some alternative techniques. For example, since openings 985 FIG. 9A and FIG. 9C (associated the locations of conductive contact 365_{WL} and structures 344 and 344′ in FIGS. 12A and 12C) are formed over part of structures 385′ (FIG. 9A and FIG. 9C) that are located on the same level (e.g., the levels of structures 385′), over-etching (or non-uniform etching) of some of openings 985 may be avoided. This allows end portions (e.g., portions at level 360) of conductive contact 365_{WL} and structures 344 and 344′ to be at a uniform level (e.g., at the same level 360 in FIG. 12A and FIG. 12C). The uniform level can improve connectivity of other conductive connections (e.g., conductive connections 392 in FIG. 15B) to some of conductive contact 365_{WL} and structures 344 and 344′. This can lead to improved reliability and performance of memory device 200.

In another example, without structures 385, conductive contact 365_{WL} and structures 344′ may have a relatively small contact region (e.g., region at width W1 in FIG. 3L or region at width W7 in FIG. 3N). Such a small contact region can cause conductive contacts 365_{WL} and structures 344′ to have a poor connection with other elements of memory device 200 or to be more susceptible to misalignment with a conductive connection with other elements (e.g., conductive portion 392C in FIG. 3N). This can lead to reduced reliability and poor device performance.

With the inclusion of structures 385, conductive contact 365_{WL} and structures 344′ can have a relatively larger contact region (e.g., region at width W3 in FIG. 3L or region at width W9 in FIG. 3N). A larger contact region can improve connectivity between conductive contacts 365_{WL}, structures 344′, or both and other elements (e.g., conductive connections 392 in FIG. 15B). For example, a large contact region can improve the quality of connections between conductive contacts 365_{WL}, structures 344′, or both with other elements of memory device 200. A larger contact region can also reduce misalignment between conductive contacts 365_{WL}, structures 344′, or both and other elements (e.g., conductive connections 392 in FIG. 15B). This can also lead to improved reliability and performance of memory device 200.

The illustrations of apparatuses (e.g., memory devices 100 and 200) and methods (e.g., method of forming memory device 200) are intended to provide a general understanding of the structure of various embodiments and are not intended to provide a complete description of all the elements and features of apparatuses that might make use of the structures described herein. An apparatus herein refers to, for example, either a device (e.g., any of memory devices 100 and 200) or a system (e.g., a computer, a cellular phone, or other electronic systems) that includes a device such as any of memory devices 100 and 200.

Any of the components described above with reference to FIG. 1 through FIG. 16B can be implemented in a number of ways, including simulation via software. Thus, apparatuses, e.g., memory devices 100 and 200 or part of each of these memory devices described above, may all be characterized as “modules” (or “module”) herein. Such modules may include hardware circuitry, single- and/or multi-processor circuits, memory circuits, software program modules and objects and/or firmware, and combinations thereof, as desired and/or as appropriate for particular implementations of various embodiments. For example, such modules may be included in a system operation simulation package, such as a software electrical signal simulation package, a power usage and ranges simulation package, a capacitance-inductance simulation package, a power/heat dissipation simulation package, a signal transmission-reception simulation package, and/or a combination of software and hardware used to operate or simulate the operation of various potential embodiments.

Memory devices 100 and 200 may be included in apparatuses (e.g., electronic circuitry) such as high-speed computers, communication and signal processing circuitry, single- or multi-processor modules, single or multiple embedded processors, multicore processors, message information switches, and application-specific modules including multilayer, multichip modules. Such apparatuses may further be included as subcomponents within a variety of other apparatuses (e.g., electronic systems), such as televisions, cellular telephones, personal computers (e.g., laptop computers, desktop computers, handheld computers, tablet computers, etc.), workstations, radios, video players, audio players (e.g., MP3 [Motion Picture Experts Group, Audio Layer 3] players), vehicles, medical devices (e.g., heart monitor, blood pressure monitor, etc.), set top boxes, and others.

The embodiments described above with reference to FIG. 1 through FIG. 16B include apparatuses and methods of forming the apparatuses. One of the methods includes: a first structure including at least one level of material; a second structure of materials formed in the first structure; levels of conductive materials interleaved with levels of dielectric materials, the levels of conductive materials and levels of dielectric materials located over the first structure and the second structure; a memory cell pillar extending through the levels of conductive materials and the levels of dielectric materials; and a conductive contact extending through the levels of conductive materials and the levels of dielectric materials and contacting one of the levels of conductive materials, the conductive contact including a portion adjacent the second structure. Other embodiments including additional apparatuses and methods are described.

In the detailed description and the claims, the term “on” used with respect to two or more elements (e.g., materials), one “on” the other, means at least some contact between the elements (e.g., between the materials). The term “over” means the elements (e.g., materials) are in close proximity, but possibly with one or more additional intervening elements (e.g., materials) such that contact is possible but not required. Neither “on” nor “over” implies any directionality as used herein unless stated as such.

In the detailed description and the claims, the terms “first”, “second”, and “third”, etc. are used merely as labels, and are not intended to impose numerical requirements on their objects.

In the detailed description and the claims, a list of items joined by the term “at least one of” can mean any combination of the listed items. For example, if items A and B are listed, then the phrase “at least one of A and B” means A only; B only; or A and B. In another example, if items A, B, and C are listed, then the phrase “at least one of A, B and C” means A only; B only; C only; A and B (excluding C); A and C (excluding B); B and C (excluding A); or all of A, B, and C. Item A can include a single element or multiple elements. Item B can include a single element or multiple elements. Item C can include a single element or multiple elements.

In the detailed description and the claims, a list of items joined by the term “one of” can mean only one of the list items. For example, if items A and B are listed, then the phrase “one of A and B” means A only (excluding B), or B only (excluding A). In another example, if items A, B, and C are listed, then the phrase “one of A, B and C” means A only; B only; or C only. Item A can include a single element or multiple elements. Item B can include a single element or multiple elements. Item C can include a single element or multiple elements.

The above description and the drawings illustrate some embodiments of the inventive subject matter to enable those skilled in the art to practice the embodiments of the inventive subject matter. Other embodiments may incorporate structural, logical, electrical, process, and other changes. Examples merely typify possible variations. Portions and features of some embodiments may be included in, or substituted for, those of others. Many other embodiments will be apparent to those of skill in the art upon reading and understanding the above description.

What is claimed is:

1. An apparatus comprising:
a first structure including at least one level of material;
a second structure of materials formed in the first structure;
levels of conductive materials interleaved with levels of dielectric materials, the levels of conductive materials and levels of dielectric materials located over the first structure and the second structure;
a memory cell pillar extending through the levels of conductive materials and the levels of dielectric materials; and
a conductive contact extending through the levels of conductive materials and the levels of dielectric materials and contacting one of the levels of conductive materials, the conductive contact including a portion adjacent the second structure.

2. The apparatus of claim 1, wherein the second structure includes a liner formed in the first structure.

3. The apparatus of claim 1, wherein:
the portion adjacent the second structure is a first portion of the conductive contact, and the first portion includes a first width;
the conductive contact includes a second portion, the second portion including a second width, wherein the first portion is between the second portion and the second structure, and the second width is greater than the first width; and
the second structure includes a third width, and the third width is greater than the first width.

4. The apparatus of claim 1, further comprising;
an additional structure formed in the first structure;
a pillar structure extending through the conductive materials and level of dielectric materials and electrically separated from levels of conductive materials, the pillar structure including a portion adjacent the additional structure.

5. The apparatus of claim 4, wherein the pillar structure includes:
a dielectric liner adjacent the levels of conductive materials and levels of dielectric materials; and
a conductive material adjacent the dielectric liner.

6. The apparatus of claim 4, wherein the pillar structure includes:
a dielectric liner adjacent the levels of conductive materials and levels of dielectric materials; and
a semiconductor material adjacent the dielectric liner.

7. The apparatus of claim 1, wherein the memory cell pillar includes memory cells, and the levels of conductive materials form control gates associated with the memory cells.

8. The apparatus of claim 7, wherein the first structure includes a conductive region, and the memory cell pillar extends at least partially into the conductive region.

9. An apparatus comprising:
a structure including at least one level of material;
a first additional structure of materials formed in the structure;
a second additional structure of materials formed in the structure;
levels of first materials interleaved levels of second materials, the levels of first materials and the levels of second materials located over the structure, the first additional structure, and the second additional structure;
a first pillar structure extending through the levels of first materials and the levels of second materials the pillar structure including a portion adjacent the first additional structure; and
a second pillar structure extending through the levels of first materials and the levels of second materials the pillar structure including a portion adjacent the second additional structure.

10. The apparatus of claim 9, wherein:
the levels of first materials include levels of silicon dioxide; and
the levels of second materials include silicon nitride.

11. The apparatus of claim 9, wherein:
the levels of first materials include levels of silicon dioxide; and
the levels of second materials include levels of conductive materials.

12. The apparatus of claim 9, wherein the structure includes a level of polysilicon.

13. The apparatus of claim 12, wherein the structure includes:
a first level of dielectric material adjacent the level of polysilicon; and
a second level of dielectric material adjacent the level of polysilicon.

14. The apparatus of claim 9, wherein:
the portion of the first pillar structure adjacent the first additional structure is a first portion of the first pillar structure, the first portion including a first width;
the first pillar structure includes a second portion, the second portion including a second width, wherein the first portion is between the second portion and the first additional structure, and the second width is greater than the first width; and
the first additional structure includes a third width, and the third width is greater than the first width.

15. The apparatus of claim 9, further comprising a conductive connection coupled to the first pillar structure.

16. The apparatus of claim 9, wherein:
the first pillar structure includes a dielectric liner adjacent the levels of first materials and the levels of second materials; and
a conductive material adjacent the dielectric liner.

17. The apparatus of claim 16, wherein:
the second pillar structure includes an additional dielectric liner adjacent the levels of first materials and the levels of second materials; and
a semiconductor material adjacent the additional dielectric liner.

18. A method comprising:
forming a first structure including forming multiple levels of materials of the first structure;
forming a second structure in the first structure including forming a liner in the first structure;
forming, over the first structure and the second structure, levels of first dielectric materials and level of second materials interleaved with the levels of first materials; and
forming a pillar structure extending through the levels of first materials and the levels of second materials, forming the pillar structure including forming a dielectric liner adjacent through the levels of first materials and the levels of second materials, and forming a material adjacent the dielectric liner and contacting the second structure.

19. The method of claim 18, wherein forming the first structure includes:
forming a level of polysilicon material; and
forming a level of dielectric material adjacent level of polysilicon material.

20. The method of claim 18, further comprising:
forming a conductive portion coupled to the material of the pillar structure, such that the second structure is between the connective portion and the pillar structure.
